(19) United States
(12) Patent Application Publication
(10) Pub. No.: US 2025/0223492 A1
(43) Pub. Date: Jul. 10, 2025

(54) BIVALENT PLATINUM OR PALLADIUM METAL COMPLEX PHOSPHORESCENT MATERIAL BASED ON DIBENZOTHIOPHENE COORDINATION AND USE THEREOF

(71) Applicants: ZHEJIANG UNIVERSITY OF TECHNOLOGY, Hangzhou (CN); ZHEJIANG HUAXIAN PHOTOELECTRICITY TECHNOLOGY CO.,LTD, Jiaxing (CN)

(72) Inventors: Guijie LI, Hangzhou (CN); Feng ZHAN, Hangzhou (CN); Guoliang LIN, Hangzhou (CN); Yuanbin SHE, Hangzhou (CN); Tengshuo ZHANG, Hangzhou (CN); Yunfang YANG, Hangzhou (CN); Xiaoyu ZHAO, Jiaxing (CN)

(73) Assignees: ZHEJIANG UNIVERSITY OF TECHNOLOGY, Hangzhou (CN); ZHEJIANG HUAXIAN PHOTOELECTRICITY TECHNOLOGY CO.,LTD, Jiaxing (CN)

(21) Appl. No.: 18/982,804

(22) Filed: Dec. 16, 2024

(30) Foreign Application Priority Data
Jan. 10, 2024 (CN) 2024100337057

(51) Int. Cl. C09K 11/06; C07F 15/00; H10K 50/12; H10K 85/30

(52) U.S. Cl. CPC C09K 11/06; C07F 15/006; C07F 15/0086; H10K 85/346; C09K 2211/1007; C09K 2211/1029; C09K 2211/1092; C09K 2211/185; H10K 50/12

(57) ABSTRACT

The present invention provides a bivalent platinum or palladium metal complex phosphorescent material based on dibenzothiophene coordination and the use thereof. Wherein the phosphorescent material has the general structure shown in Formula (I):

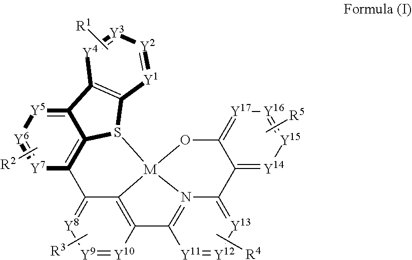

The complexes of the present invention are based on novel tetradentate ligands of 4-phenyldibenzothiophene and pyridoxyl anions and derivatives thereof, which are coordinated with central metal ions to form 6/5/6 type tetradentate cyclometallated complex phosphorescent materials, and the presence of Pt—S coordination bonds makes such materials have significant temperature response characteristics. The luminescence intensity increases with the decrease of temperature, and the emission wavelength blue-shifted with the decrease of temperature. The blue-green luminescence was observed at 77 K, but the yellow luminescence was observed at 289 K, which indicated the potential application in optical thermometers.

### CROSS-REFERENCE TO RELATED APPLICATIONS

The application claims priority to Chinese patent application No. 202410033705.7, filed on Jan. 10, 2024, the entire contents of which are incorporated herein by reference.

### TECHNICAL FIELD

The present invention relates to the technical field of the preparation of metal organic optoelectronic functional materials, and in particular to a bivalent platinum or palladium metal complex phosphorescent material based on dibenzothiophene coordination and the use thereof.

### BACKGROUND

In the past few decades, tetradentate Pt (II) complexes have attracted considerable attention due to the strong spin-orbit coupling of Pt atoms and the fact that tetradentate cyclometallated ligands can form square planar rigid structures that suppress nonradiative decay. Furthermore, the photophysical properties of Pt (II) complexes can be adjusted by using ligands with different coordination sites, coordination bonds, and coordination moieties. To date, most studies have focused on the coordination of carbon (Carbene), oxygen (O), and nitrogen (N) atoms with the Pt (II) metal to form a strong field ligand, contributing to stronger coordination bonds. According to the hard-soft acid-base (HSAB) theory, the soft metal Pt/Pd is better matched with the soft base sulfur (S) atom to form an S coordination bond than O and N coordination bonds. Unlike sp² hybridization of coordinated N atoms, the coordinated S in Pt (II) complexes is mainly sp³ hybridization, which can distort the planar configuration and avoid molecular packing. However, previously reported Pt (II) luminescent complexes containing Pt—S coordination bonds are mainly bidentate and tridentate complexes, with few tetradentate complexes. The bidentate and tridentate Pt (II) complexes have poor electrochemical and thermal stability and low phosphorescence efficiency. Compared with the bidentate and tridentate Pt (II) complexes, the tetradentate Pt (II) complexes have a planar structure and stronger ligand rigidity, which can reduce the configuration change of the material molecule in the excited state, thus reducing the nonradiative attenuation due to molecular vibration and rotation, improve the quantum efficiency, and also improve the molecular chemical and thermal stability. Although bivalent platinum or palladium complex phosphors have been reported, most of them have been used in the OLED field. It is still of great significance to exploit the advantages of tetradentate Pt (II) phosphorescent materials in other fields.

### SUMMARY

The present invention addresses the deficiencies of the prior art and aims to provide a bivalent platinum or palladium metal complex phosphorescent material based on dibenzothiophene coordination. The provided materials have temperature response characteristics, and the corresponding relationship between temperature and fluorescence intensity can be obtained without the addition of reference or calibration, showing significant differences in luminescence color at different temperatures, and the temperature of materials can be estimated by the naked eye. In the field of temperature response such as optical thermometers, it has a very high application prospect.

In order to achieve the object, the technical solution of the present invention is as follows:

The present invention provides a bivalent platinum or palladium metal complex phosphorescent material based on dibenzothiophene coordination having a general structure shown in the following Formula (I):

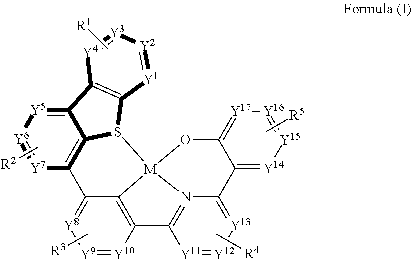

wherein: M is Pt or Pd;
Y¹-Y¹⁷ are each independently selected from N or C atoms;

R¹, R², R³, R⁴, and R⁵ can be each independently mono-, di-, tri-, tetra- or unsubstituted; R¹, R² are each independently represented by any one of hydrogen, deuterium, halogen, —CN, substituted or unsubstituted C1-C24 alkyl, substituted or unsubstituted C1-C24 alkoxy, substituted or unsubstituted C1-C24 silyl, substituted or unsubstituted C6-C36 aryl, or a combination thereof;

R³ is represented by any one of hydrogen, deuterium, halogen, —CN, substituted or unsubstituted C1-C24 alkyl, substituted or unsubstituted C1-C24 cycloalkyl, substituted or unsubstituted C3-C24 heterocycloalkyl, substituted or unsubstituted C1-C24 alkoxy, substituted or unsubstituted C6-C36 aryl, C6-C36 heteroaryl, substituted or unsubstituted C6-C36 arylamino, substituted or unsubstituted C6-C36 heteroarylamino, substituted or unsubstituted C1-C24 alkylamino, or a combination thereof, the heteroatoms in the heterocycloalkyl, heteroaryl groups can be selected from N, O, S or Si; the heteroatom in the heteroarylamino can be selected from O, S or Si;

R⁴ and R⁵ are each independently represented by one or more combinations of hydrogen, deuterium, halogen, —CN, substituted or unsubstituted C1-C24 alkyl, substituted or unsubstituted C1-C24 cycloalkyl, substituted or unsubstituted C3 to C24 heterocycloalkyl, substituted or unsubstituted C1-C24 alkoxy, substituted or unsubstituted C6-C36 aryl; when a substituent is present in the foregoing groups, the substituents are each independently selected from any one of deuterium, halogen, —CN, C1-C10 alkyl, C3-C10 cycloalkyl, C6-C30 aryl, or a combination thereof.

All the hydrogen atoms in Formula (I) may be substituted by deuterium atoms.

Any two substituents of Formula (I) may be joined or fused together to form a ring.

Preferably, two or more adjacent R¹, R², R³, R⁴, and R⁵ may be optionally linked to form a ring.

R¹ and R² are each independently represented by any one of hydrogen, deuterium, F, —CN, methyl, ethyl, propyl, isopropyl, tert-butyl, phenyl, methoxy, trimethylsilane, or a combination thereof.

R³ is represented by any one of hydrogen, deuterium, F, —CN, methyl, ethyl, propyl, isopropyl, tert-butyl, heptyl, cyclopentane, pyridyl, carbazolyl, diphenylamino, phenothiazinyl, phenoxazinyl, phenyl, methoxy, trimethylsilyl, benzofuranyl, benzothienyl, pyrrolidinyl, 1,1 dimethylindenyl, or a combination thereof.

R⁴ and R⁵ are each independently represented by any one of hydrogen, deuterium, F, —CN, methyl, ethyl, propyl, isopropyl, tert-butyl, heptyl, cyclopentanyl, cyclopentenyl, phenyl, methoxy, trimethylsilyl, benzofuranyl, benzothienyl, pyrrolidinyl, 1,1 dimethylindenyl, or a combination thereof.

Further, the present invention provides a bivalent platinum or palladium metal complex phosphorescent material based on dibenzothiophene coordination, wherein the phosphorescent material is selected from one of the following structures:

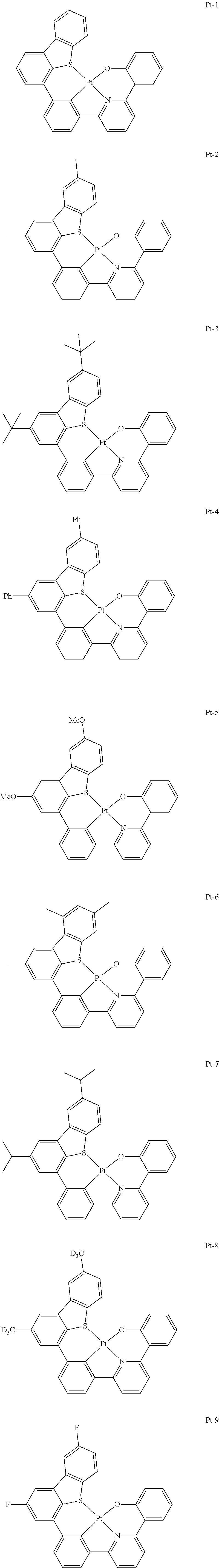

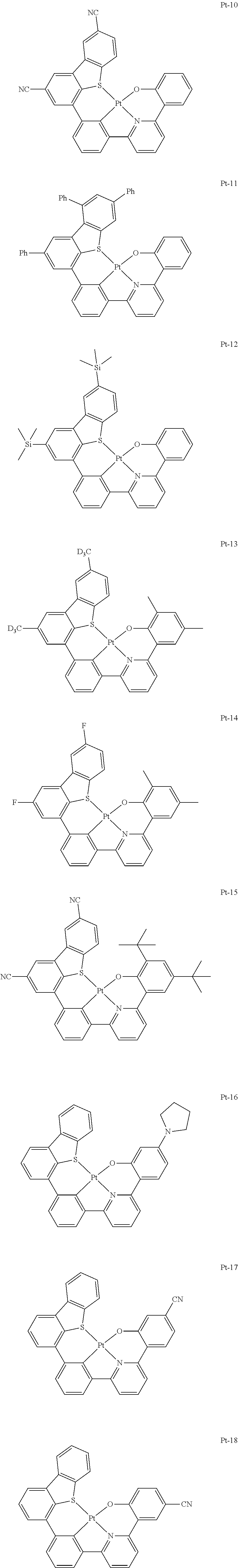

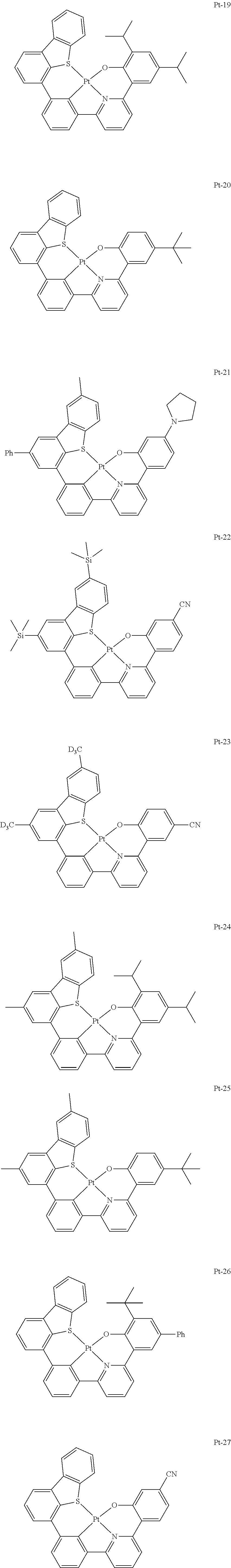

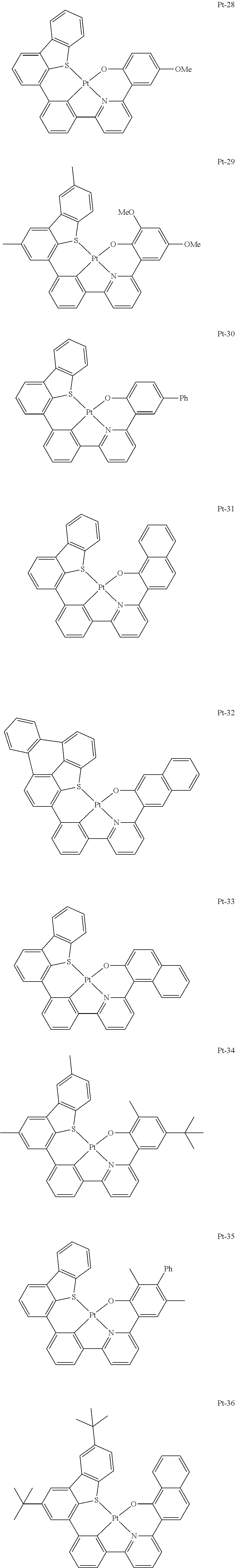

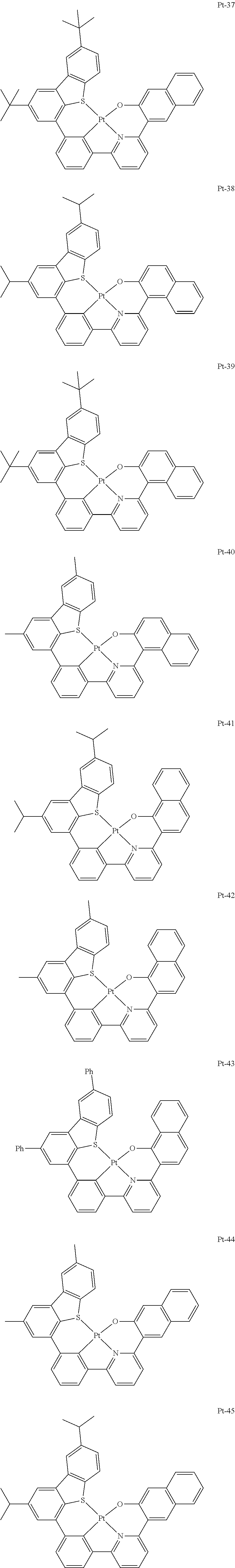

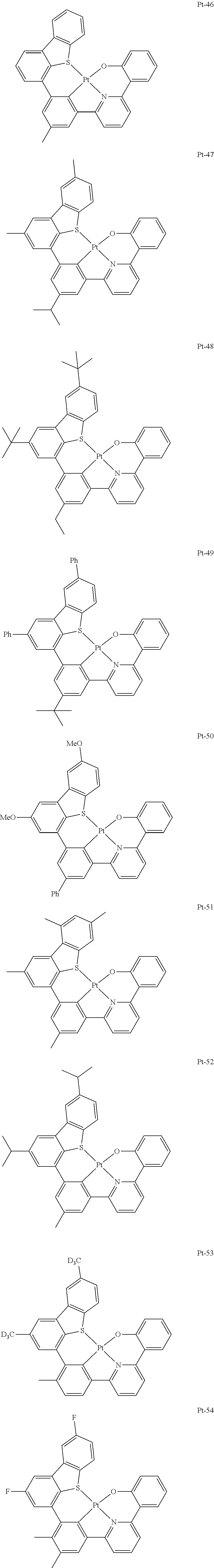

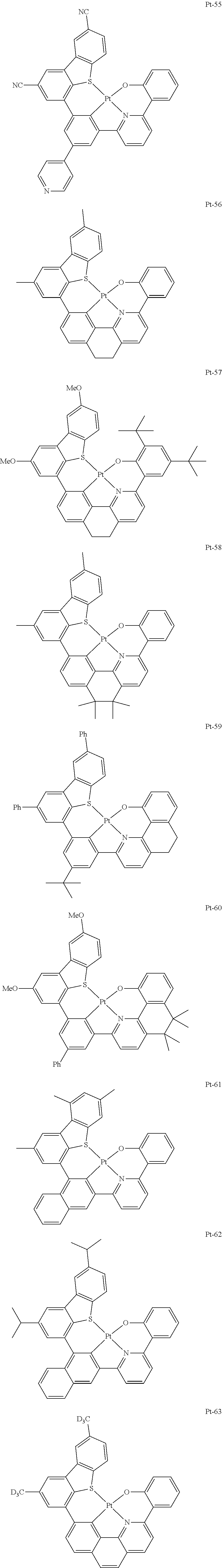

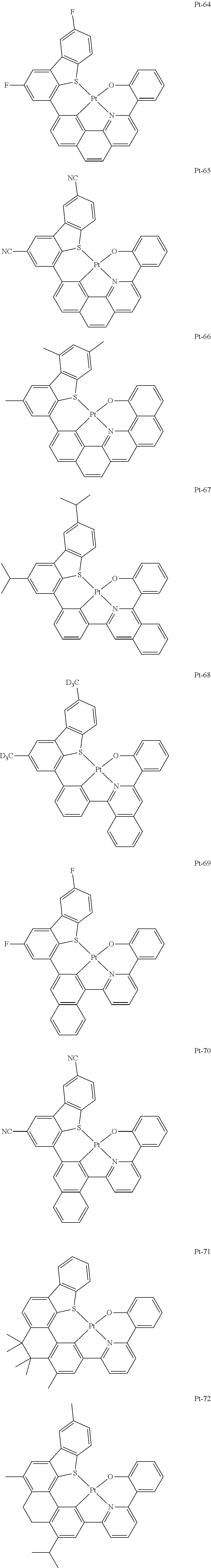

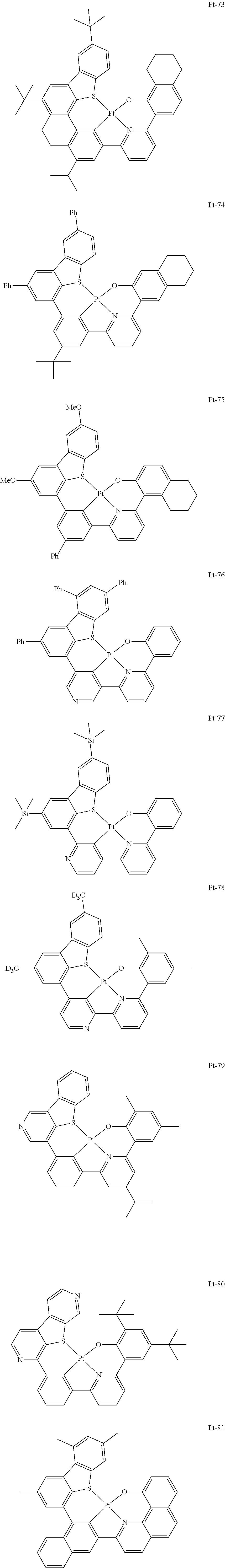

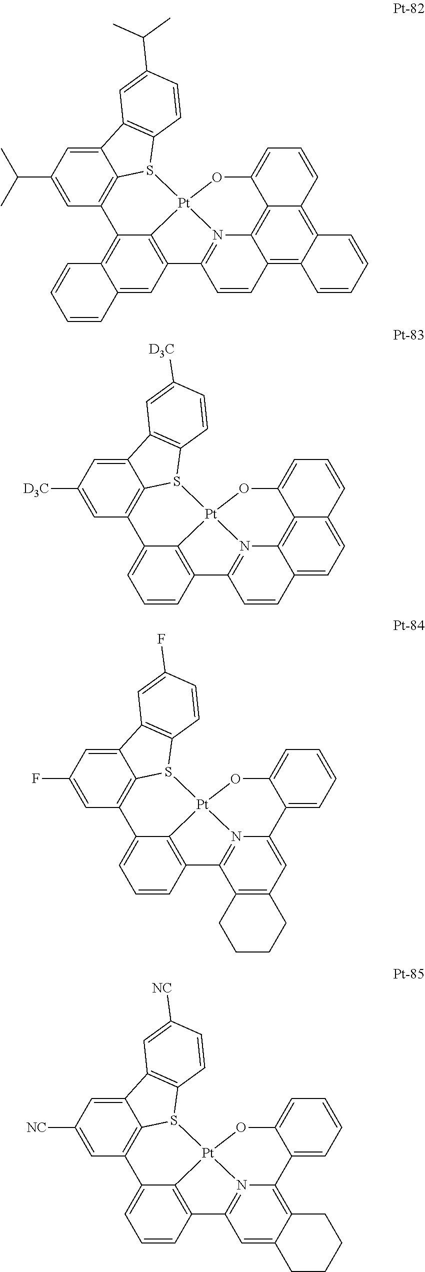

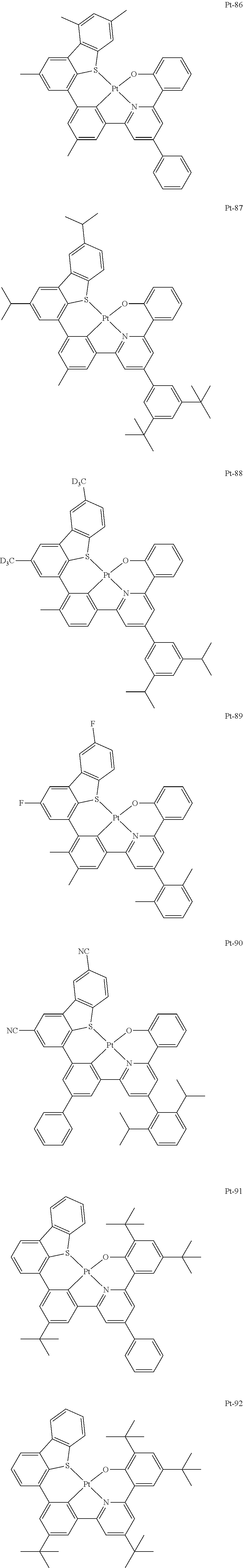

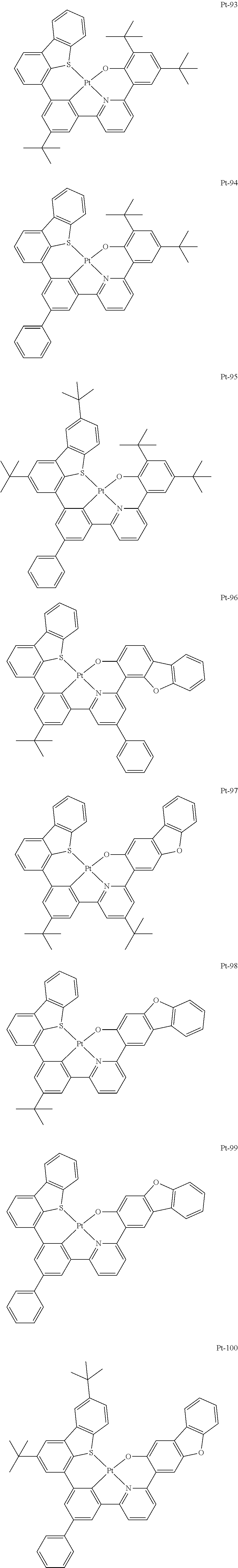

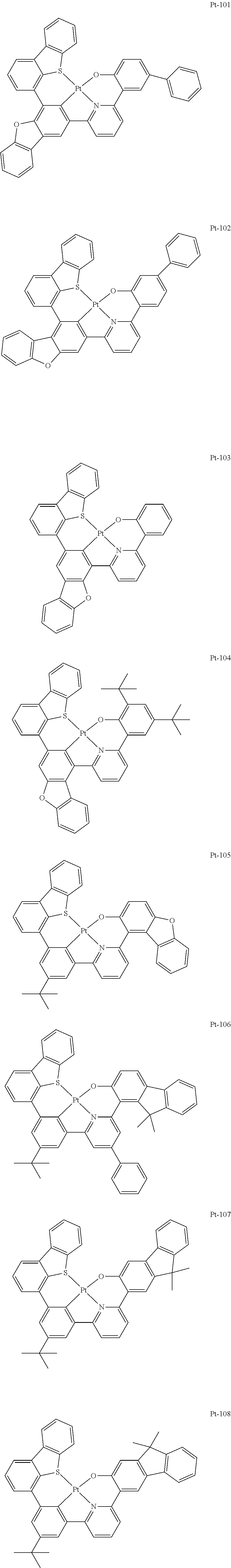

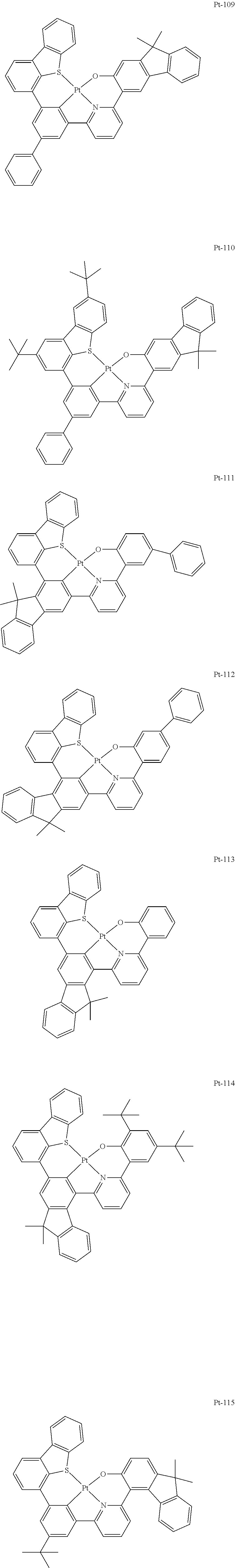

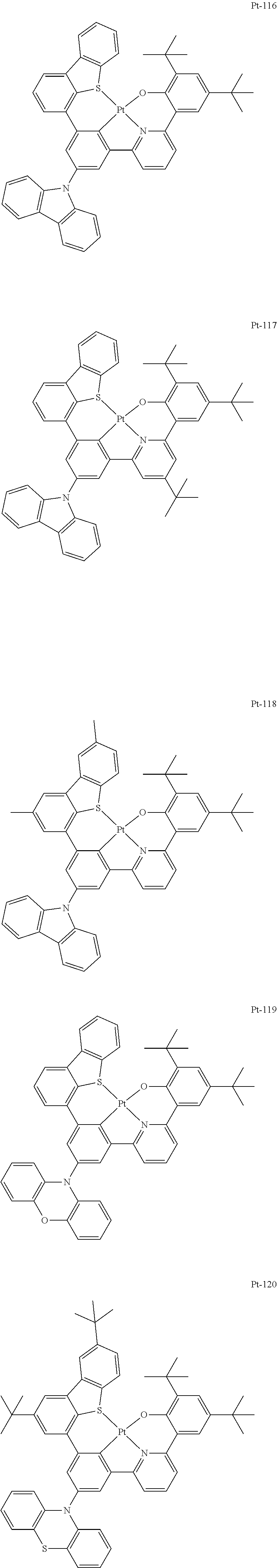

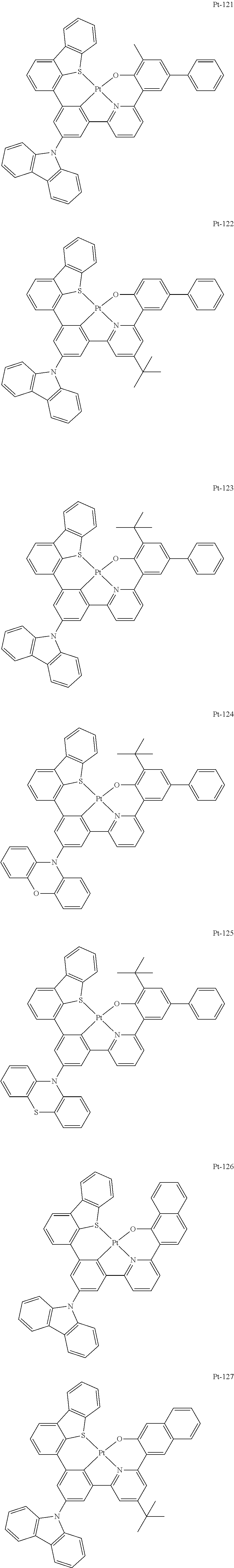

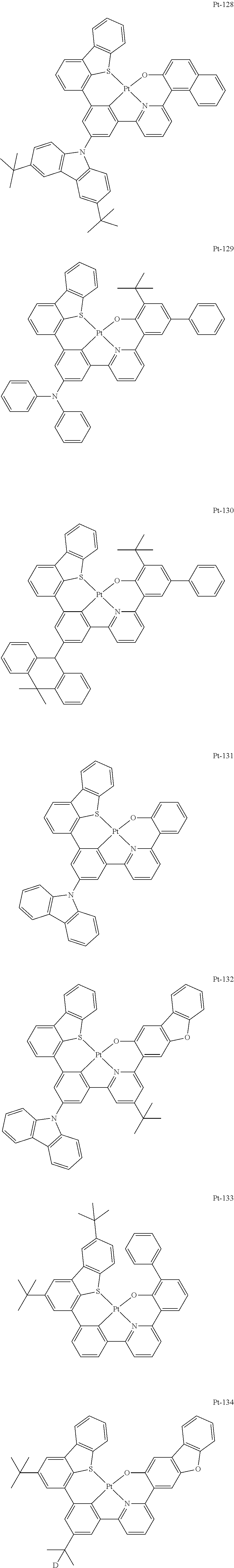

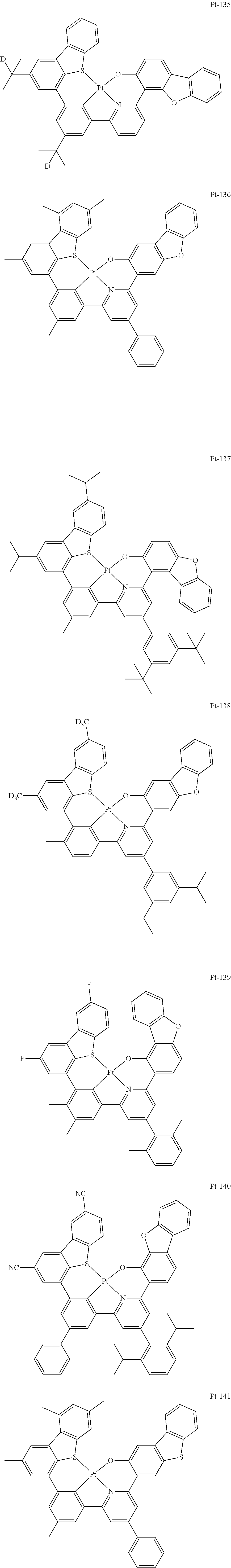

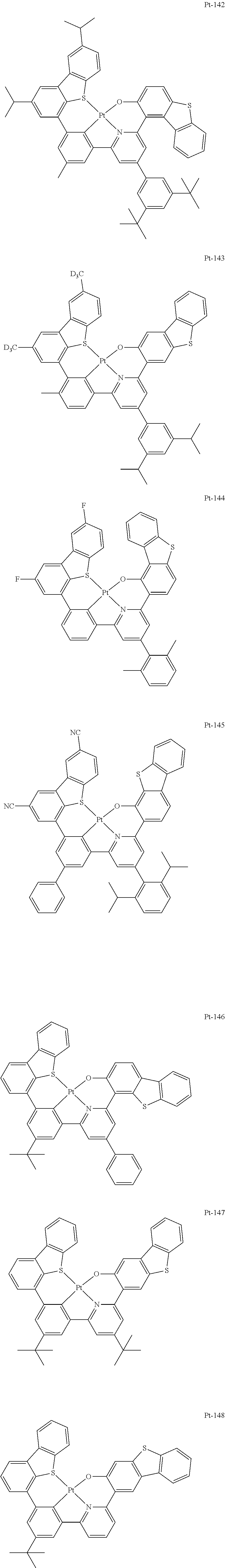

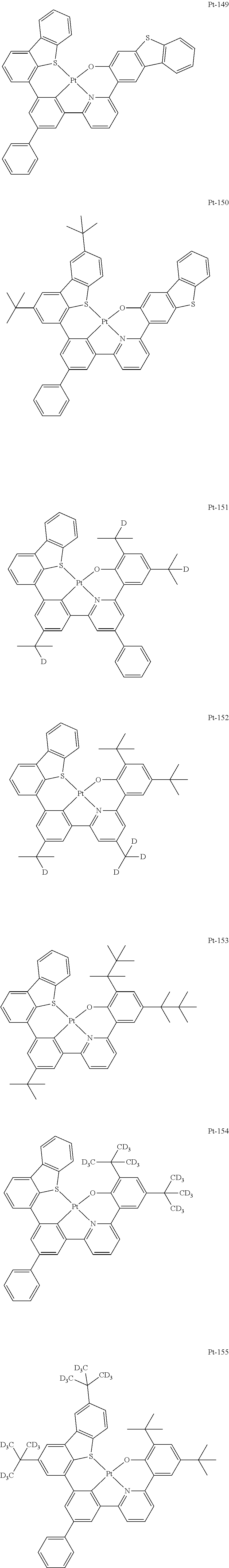

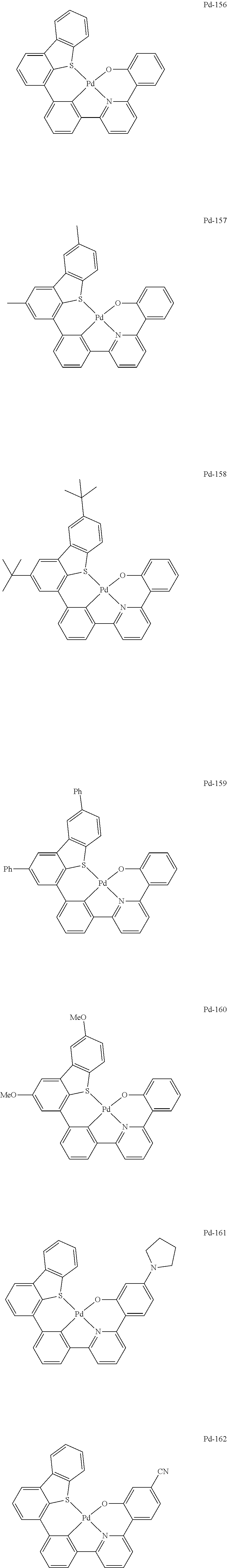

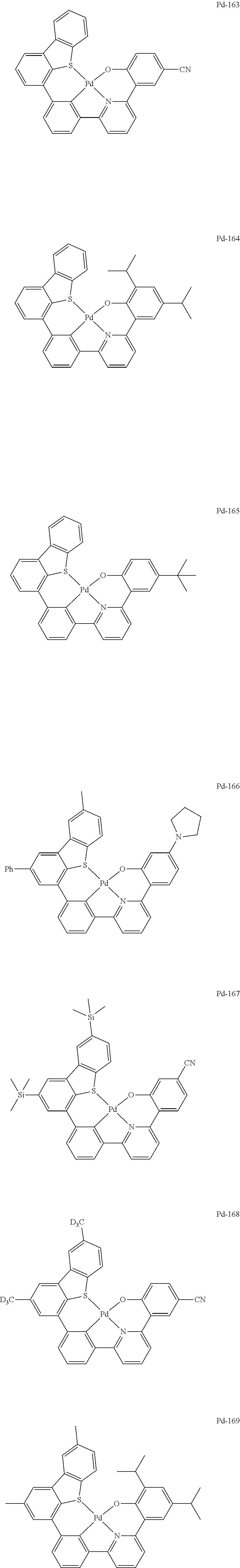

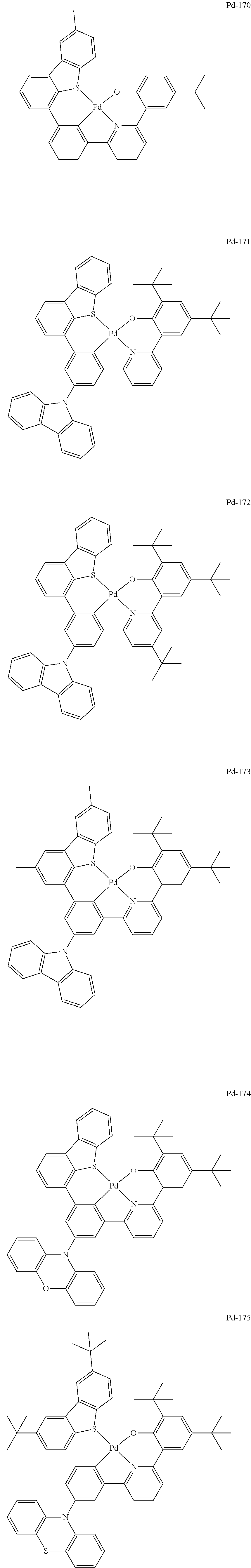

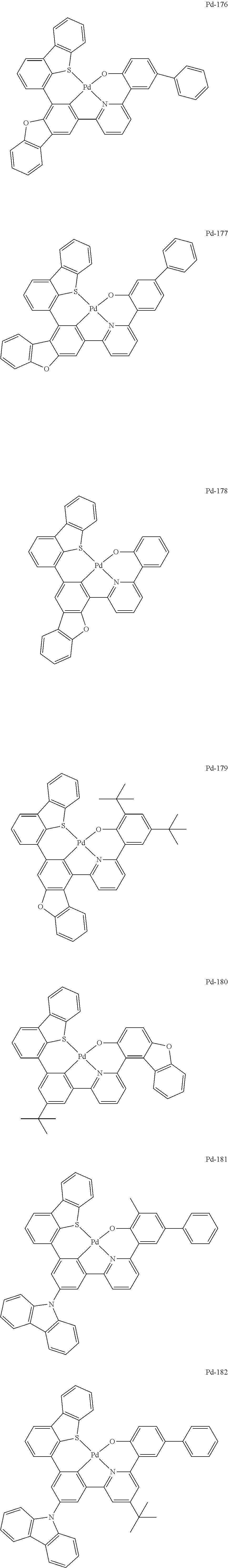

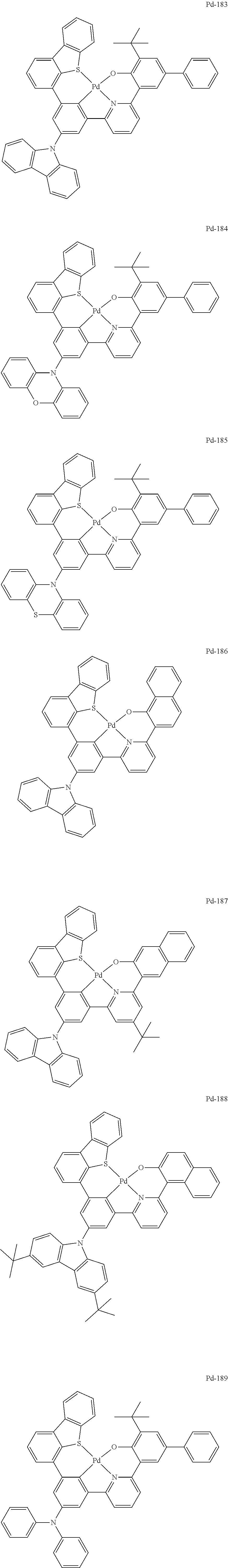

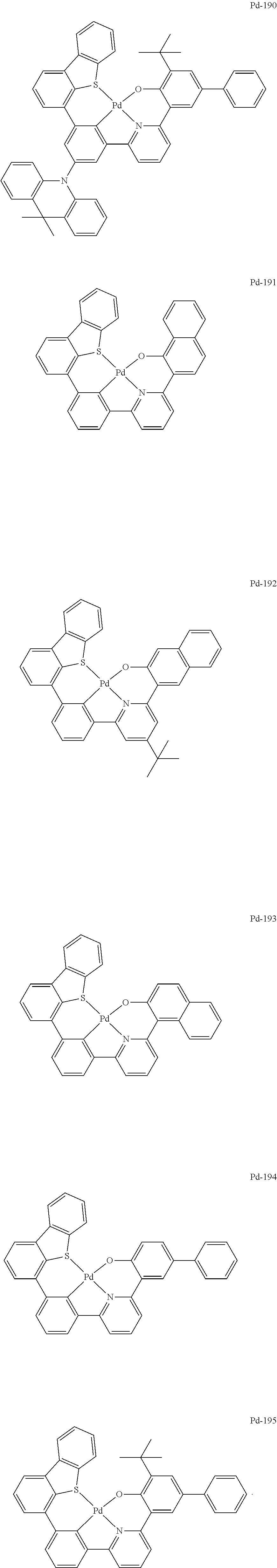

The present invention also provides the use of the bivalent platinum or palladium metal complex phosphorescent material based on dibenzothiophene coordination for producing an organic luminous element.

Preferably, the organic luminous element is an organic light-emitting diode, light-emitting diode, or light-emitting electrochemical cell.

The present invention also provides the use of the bivalent platinum or palladium metal complex phosphorescent material based on dibenzothiophene coordination as a temperature-responsive light-emitting material.

Further, the present invention also provides the use of the bivalent platinum or palladium metal complex phosphorescent material based on dibenzothiophene coordination in the preparation of an optical thermometer.

The present invention also provides an organic light-emitting diode comprising
an anode;
a cathode; and
an organic layer disposed between the anode and the cathode, wherein the organic layer comprises the bivalent platinum or palladium metal complex phosphorescent material based on dibenzothiophene coordination as described above.

The present invention also provides a consumer product comprising an organic light-emitting diode comprising
an anode;
a cathode; and
an organic layer disposed between the anode and the cathode, wherein the organic layer comprises the bivalent platinum or palladium metal complex phosphorescent material based on dibenzothiophene coordination as described above.

### Advantageous Effects of the Present Invention are

1. The molecular structure design of the materials of the present invention adopts a new dibenzothiophene unit to coordinate with the central metal ion to form a six-membered metal ring and combines o-pyridyloxyl anion and its derivatives to form a new tetradentate ligand. The tetradentate ligand coordinates with the central metal ion to form a 6/5/6 type tetradentate cyclometallated complex phosphorescent material. The presence of a Pt—S coordination bond makes such materials have obvious temperature response characteristics. The luminescence intensity of the material increases as the temperature decreases, and the emission wavelength blue-shifts as the temperature decreases. It exhibits cyan-green luminescence at 77 K but exhibits yellow luminescence as the temperature rises to 289 K.

2. The present invention reports for the first time that tetradentate platinum/palladium complex phosphorescent materials containing S-M coordination bonds, according to the hard-soft acid-base (HSAB) theory, the soft metal Pt/Pd is better matched with the soft base sulfur (S) atoms to form S coordination bonds than O and N coordination bonds. Unlike sp² hybridization of coordinated N atoms, the coordinated S in Pt (II) complexes is mainly sp³ hybridization, which can distort planar configuration, avoid molecular packing, and effectively inhibit Pt . . . Pt interactions leading to luminescence quenching.

3. The complex phosphorescent materials provided by the present invention have a temperature response characteristic in a solution state, and the relationship between temperature and fluorescence intensity can be obtained without the addition of reference or calibration, at the same time, it shows a significant difference in luminescence color at different temperatures, and the temperature of the material can be estimated by the naked eye. It can be used in the traditional tetradentate Pt complexes and can be used in temperature response fields such as optical thermometers, which expands the application scenarios.

### BRIEF DESCRIPTION OF DRAWINGS

FIG. 1 is a spectrogram of complexes Pt-1 (PtSZ) and Pt-20 (PtSZtBu) and their ligands LSZ and LSZtBu; wherein (a) is the absorption spectrum in dichloromethane, (b) is the PL spectrum in a toluene solution of 2-methyltetrahydrofuran (2-MeTHF) and RT at 77 K; (c) is the calculated frontier orbital distribution and energy level;

FIG. 2 is a single crystal structure of complexes Pt-1 and Pt-20;

FIG. 3 is a spectrogram of complex Pt-20 in tetrahydrofuran solution; in the figure, (a) is a photoluminescence spectrogram at varying temperatures, (b), (c) are transient spectra, and (d) is the change in luminescence color during the temperature increase in toluene solution; and

FIG. 4 is a theoretical calculation graph of the complex Pt-20; in the diagram, (a) is the energy diagram of the excited triplet state, (b) is the localized molecular orbital of the Pipek-Mezey localization of the Pt—S bond, (c) is the potential energy curve and optical transition of the triplet emission state (T1), and (d) is the spin density distribution of T1-MIN1/T1-TS/T1-MIN2.

### DETAILED DESCRIPTION OF THE EMBODIMENTS

Hereinafter, the present invention will be described in detail. The following description of the constituent elements is sometimes based on a representative embodiment or embodiment of the present invention, but the present invention is not limited to this embodiment or embodiment.

As used herein, the following terms, unless otherwise specified, are defined as follows:

As used herein, the term “organic” includes polymeric materials and small molecule organic materials that can be used to make organic photovoltaic devices. A “small molecule” refers to any organic material that is not a polymer, and a “small molecule” may actually be quite large. In some cases, a small molecule can include a repeating unit. For example, using a long-chain alkyl group as a substituent does not remove a molecule from the class of “small molecules”. Small molecules may also be incorporated into the polymer, for example as pendent groups on the polymer backbone or as part of the backbone. Small molecules can also serve as the core portion of a dendrimer that consists of a series of chemical shell layers built onto the core portion. The core portion of the dendrimer may be a fluorescent or phosphorescent small molecule emitter. Dendrimers can be “small molecules” and all dendrimers currently used in the OLED field are considered small molecules.

As used herein, “top” means furthest away from the substrate, and “bottom” means closest to the substrate. Where the first layer is described as being “disposed over” the second layer, the first layer is disposed further from the substrate. Other layers may be present between the first and second layers unless the first layer is specified to be “in contact with” the second layer. For example, a cathode can be described as “disposed over” an anode, even if various organic layers are present between the cathode and the anode.

The terms “halo”, “halogen” and “halo” are used interchangeably and refer to fluoro, chloro, bromo, and iodo. The term “acyl” refers to a substituted carbonyl group (C (O)—Rs). The term “ester” refers to a substituted oxycarbonyl (—O—C(O)—Rs or —C(O)—O—Rs) group. The term “ether” refers to a —ORs group. The terms “thio” or “thioether” are used interchangeably and refer to a —SRs group. The term “sulfinyl” refers to the group —S(O)—Rs. The term “sulfonyl” refers to the group —SO₂—Rs. Wherein each Rs may be the same or different. The term “silyl” refers to a —Si (Rs)₃ group, where each Rs may be the same or different.

In each of the foregoing, rs can be hydrogen or a substituent selected from the group consisting of deuterium, halogen, alkyl, cycloalkyl, heteroalkyl, heterocycloalkyl, aralkyl, alkoxy, aryloxy, amino, silyl, alkenyl, cycloalkenyl, heteroalkenyl, alkynyl, aryl, heteroaryl, and combinations thereof. Preferred Rs are selected from the group consisting of alkyl, cycloalkyl, aryl, heteroaryl, and combinations thereof.

The term “alkyl” refers to and includes both straight and branched chain alkyl groups. Preferred alkyl groups are alkyl groups containing one to fifteen carbon atoms and include methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. In addition, alkyl groups may be optionally substituted.

The term “cycloalkyl” refers to and includes monocyclic, polycyclic, and spiroalkyl groups. Preferred cycloalkyl groups are those containing from 3 to 12 ring carbon atoms and include cyclopropyl, cyclopentyl, cyclohexyl, bicyclo [3.1.1]heptyl, spiro [4.5]decyl, spiro [5.5]undecyl, adamantyl and the like. Additionally, cycloalkyl groups can be optionally substituted.

The terms “heteroalkyl” or “heterocycloalkyl” refer to an alkyl or cycloalkyl group, respectively, having at least one carbon atom replaced with a heteroatom. Optionally, at least one heteroatom is selected from O, S, N, P, B, si, and Se, preferably O, S, or N. Additionally, a heteroalkyl or heterocycloalkyl group can be optionally substituted. The term “alkenyl” refers to and includes both straight and branched chain alkenyl groups. Alkenyl is essentially an alkyl group that includes at least one carbon-carbon double bond in the alkyl chain. A cycloalkenyl group is essentially a cycloalkyl group that includes at least one carbon-carbon double bond in the cycloalkyl ring. The term “heteroalkenyl”, as used herein, refers to an alkenyl in which at least one carbon atom is replaced with a heteroatom. Optionally, at least one heteroatom is selected from O, S, N, P, B, si, and Se, preferably O, S, or N. Preferred alkenyl, cycloalkenyl, or heteroalkenyl groups are those containing from two to fifteen carbon atoms. In addition, alkenyl, cycloalkenyl, or heteroalkenyl groups may be optionally substituted.

The term “alkynyl” refers to and includes both straight and branched chain alkynyl groups. Alkynes are essentially alkyl groups that include at least one carbon-carbon triple bond in the alkyl chain. Preferred alkynyl groups are those containing two to fifteen carbon atoms. In addition, alkynyl groups may be optionally substituted. The terms “aralkyl” or “arylalkyl” are used interchangeably and refer to an alkyl group substituted with an aryl group. Additionally, aralkyl groups can be optionally substituted.

The term “heterocyclyl” refers to and includes aromatic and non-aromatic cyclic groups containing at least one heteroatom. Optionally, at least one heteroatom is selected from O, S, N, P, B, si, and Se, preferably O, S, or N. Aromatic heterocyclic groups may be used interchangeably with heteroaryl groups. Preferred non-aromatic heterocyclic groups are heterocyclic groups containing from 3 to 7 ring atoms including at least one heteroatom, and include cyclic amines such as morpholinyl, piperidinyl, pyrrolidinyl, and the like, and cyclic ethers/thioethers such as tetrahydrofuran, tetrahydropyran, tetrahydrothiophene, and the like. Additionally, heterocyclyl groups may be optionally substituted.

The term “aryl” refers to and includes monocyclic aromatic hydrocarbon groups and polycyclic aromatic ring systems. Polycycles can have two or more rings in which two carbons are common to two adjoining rings (the rings are “fused”), wherein at least one of the rings is an aromatic hydrocarbon group, e.g. the other rings can be cycloalkyls, cycloalkenyls, aryls, heterocycles, and/or heteroaryls. Preferred aryl groups are aryl groups containing six to thirty carbon atoms, preferably six to twenty carbon atoms, more preferably six to twelve carbon atoms. Particularly preferred are aryl groups having six carbons, ten carbons, or twelve carbons. Suitable aryl groups include phenyl, biphenyl, terphenyl, triphenylene, tetraphenylene, naphthalene, anthracene, phenalene, phenanthrene, fluorene, pyrene, perylene, and azulene, preferably phenyl, biphenyl, terphenyl, triphenylene, fluorene, and naphthalene. In addition, aryl groups may be optionally substituted.

The term “heteroaryl” refers to and includes monocyclic aromatic groups and polycyclic aromatic ring systems that include at least one heteroatom. Heteroatoms include, but are not limited to, O, S, N, P, B, si, and Se. In many cases, O, S or N are preferred heteroatoms. Monocyclic heteroaromatic systems are preferably monocyclic having 5 or 6 ring atoms, and the ring may have from one to six heteroatoms. A heteropolycyclic ring system may have two or more rings in which two atoms are common to two adjoining rings (the rings are “fused”) wherein at least one of the rings is heteroaryl, e.g. the other rings may be cycloalkyls, cycloalkenyls, aryls, heterocycles, and/or heteroaryls. The heteropolycyclic aromatic ring systems may have from one to six heteroatoms in each ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indolizine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzselenophenopyridine and selenophenodipyridine; preferably, dibenzothiophenes, dibenzofurans, dibenzoselenophenes, carbazoles, indolocarbazoles, imidazoles, pyridines, triazines, benzimidazoles, 1,2-azaboranes, 1,3-azaboranes, 1,4-azaboranes, borazynes and aza analogues thereof. Additionally, heteroaryl groups can be optionally substituted.

Of the aryl and heteroaryl groups listed above, triphenylene, naphthalene, anthracene, dibenzothiophene, dibenzofuran, dibenzoselenophene, carbazole, indolocarbazole, imidazole, pyridine, pyrazine, pyrimidine, triazine and benzimidazole, and their respective corresponding aza analogs are of particular interest.

The terms alkyl, cycloalkyl, heteroalkyl, heterocycloalkyl, alkenyl, cycloalkenyl, heteroalkenyl, alkynyl, aralkyl, heterocyclyl, aryl, and heteroaryl as used herein are independently unsubstituted or independently substituted with one or more generic substituents.

In many cases, typical substituents are selected from the group consisting of deuterium, halogen, alkyl, cycloalkyl, heteroalkyl, heterocycloalkyl, aralkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, thio, sulfinyl, sulfonyl, phosphinyl, and combinations thereof.

In some cases, preferred general substituents are selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, thio, and combinations thereof.

In some cases, preferred general substituents are selected from the group consisting of deuterium, fluorine, alkyl, cycloalkyl, alkoxy, aryloxy, amino, silyl, boryl, aryl, heteroaryl, thio, and combinations thereof.

In other cases, more preferred general substituents are selected from the group consisting of deuterium, fluorine, alkyl, cycloalkyl, aryl, heteroaryl, and combinations thereof.

The terms “substituted” and “substitute” mean that a substituent other than His bonded to the relevant position, e.g. carbon or nitrogen. For example, when R₁ represents monosubstituted, then one R₁ must not be H (i.e. substituted). Similarly, when R₁ represents disubstituted, then both R₁ must not be H. Similarly, when R₁ represents zero or no substitution, R₁ may, for example, be hydrogen having an available valence of a ring atom, such as a carbon atom of benzene and a nitrogen atom in pyrrole, or, for a ring atom having a fully saturated valence, simply represent no, such as a nitrogen atom in pyridine. The maximum number of substitutions possible in a ring structure will depend on the total number of available valences in the ring atoms.

As used herein, “a combination thereof” means that one or more members of the applicable list are combined to form a known or chemically stable arrangement that one of ordinary skill in the art can envision from the applicable list. For example, alkyl and deuterium may combine to form a partially or fully deuterated alkyl; halogen and alkyl may combine to form a haloalkyl substituent; and halogen, alkyl, and aryl may combine to form a haloaralkyl. In one example, the term substituted includes combinations of two to four of the listed groups. In another example, the term substituted includes combinations of two to three groups. In yet another example, the term substitution includes a combination of two groups. Preferred combinations of substituents are combinations containing up to fifty atoms other than hydrogen or deuterium, or combinations comprising up to forty atoms other than hydrogen or deuterium, or combinations comprising up to thirty atoms other than hydrogen or deuterium. In many cases, preferred combinations of substituents will include up to twenty atoms that are not hydrogen or deuterium.

As used herein, “deuterium” refers to an isotope of hydrogen. Deuterated compounds can be readily prepared using methods known in the art.

It will be understood that when a molecular fragment is described as a substituent or otherwise attached to another moiety, its name can be written as if it were a fragment (e.g. phenyl, phenylene, naphthyl, dibenzofuranyl) or as if it were the entire molecule (e.g. benzene, naphthalene, dibenzofuran). As used herein, these different ways of naming substituents or linking moieties are considered equivalent.

In some cases, a pair of adjacent substituents may optionally be joined or fused to form a ring. Preferred rings are five-, six-, or seven-membered carbocyclic or heterocyclic rings, including both cases where a portion of the ring formed by the pair of substituents is saturated and a portion of the ring formed by the pair of substituents is unsaturated. As used herein, “adjacent” means that two substituents referred to may be immediately adjacent to each other on the same ring, or on two adjacent rings having two nearest available substitutable positions, such as the 2, 2′positions in biphenyl or the 1, 8 positions in naphthalene, so long as they can form a stable fused ring system.

In some embodiments, the consumer product may be one of the following products: flat panel displays, computer monitors, medical monitors, televisions, billboards, lights for internal or external lighting and/or signaling, heads-up displays, fully transparent or partially transparent displays, flexible displays, laser printers, telephones, cellular telephones, tablet computers, tablet cell phones, personal digital assistants (PDA), wearable devices, laptop computers, digital cameras, video cameras, viewfinders, microdisplays with less than 2 inches diagonal, 3-D displays, virtual reality or augmented reality displays, vehicles, a video wall comprising a plurality of displays tiled together, a theater or stadium screen, a phototherapy device, and a sign.

Specific examples of the divalent platinum metal complex (phosphorescent material) of the present invention represented by the following general formula (1) are illustrated below, however, are not to be construed as limiting the present invention.

### EXAMPLES

Unless otherwise noted, all commercially available reagents referred to in the following examples were used as received without further purification. Proton NMR spectra were measured in deuterated chloroform (CDCl₃) or deuterated dimethylsulfoxide (DMSO-d₆) solutions using a 400 or 500 MHz NMR spectrometer. If CDCl₃ is used as a solvent, the hydrogen spectrum uses CDCl₃ (6=7.26 ppm) as an internal standard. If DMSO-d₆ is used as a solvent, the hydrogen spectrum uses DMSO-d₆ (6=2.50 ppm) as an internal standard. The following abbreviations (or combinations) are used to explain the hydrogen spectra peaks: S=singlet, d=doublet, t=triplet, q=quartet, p=pentet, m=multiplet, br=broad. Density functional theory (DFT) was used to optimize the geometrical structure of ground state (S₀) molecules of the metal complex; DFT calculations were performed using the B3LYP functional where the 6-31G(d) basis set was used for C, H, O, S and N atoms and the LANL2DZ basis set was used for Pt and Pd atoms.

Example 1: The synthesis route of tetradentate cyclometallated platinum (II) complex phosphorescent light-emitting material Pt-1 is as follows:

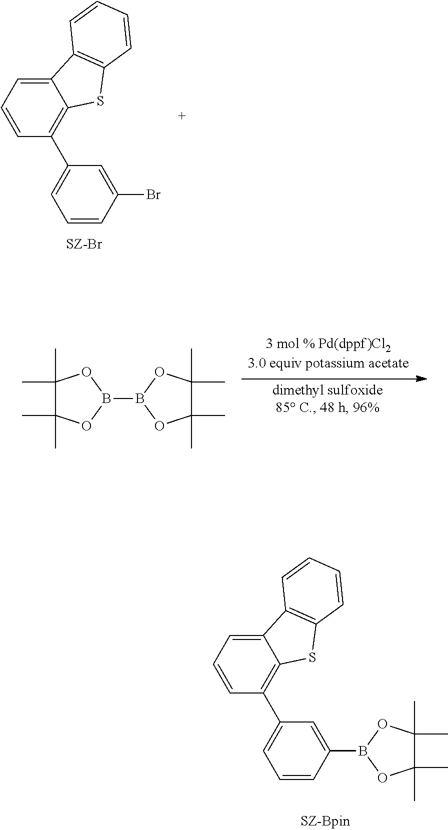

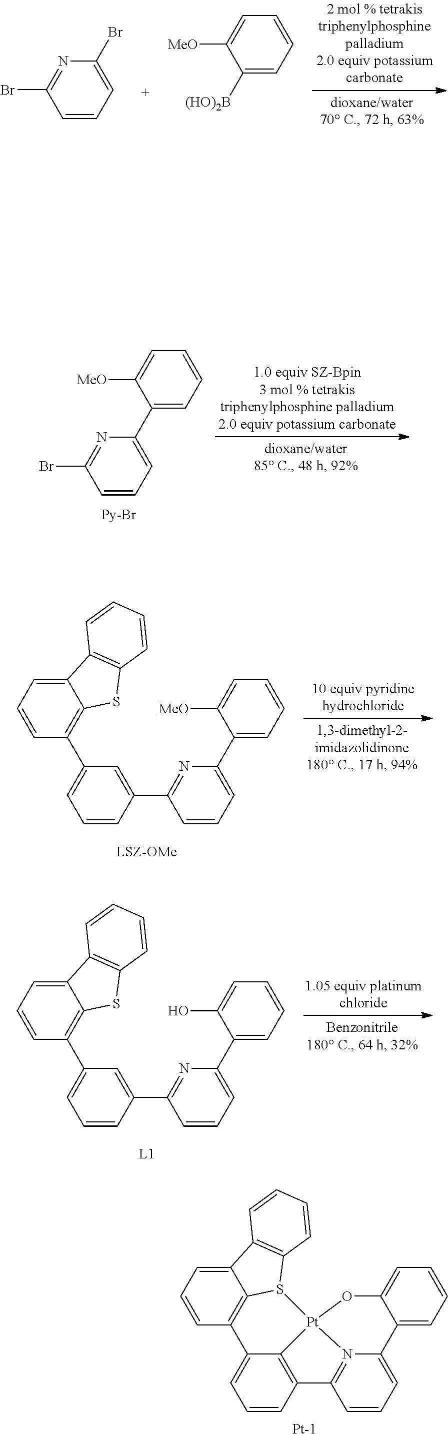

Synthesis of intermediate (SZ-Bpin): SZ-Br (2.00 g, 5.90 mmoL, 1.00 equiv), bis(pinacolato)diboron (2.25 g, 8.84 mmoL, 1.50 equiv), pd(dppf)Cl₂ (130 mg, 0.18 mmoL, 3 mmoL %) and anhydrous potassium acetate (1.74 g, 17.70 mmoL, 3.0 equiv) were charged into a dry flask, the oil pump was purged with nitrogen three times, and dimethyl sulfoxide (30 mL) was added via syringe, and the reaction was carried out at 85° C. for 48 h. After naturally cooling to normal temperature, ethyl acetate was added, washed with deionized water, concentrated by rotary evaporation, and further purified by silica gel chromatography column using petroleum ether/ethyl acetate=100:1 as eluent, concentrated to give 2.18 g of a white solid product in a yield of 96%. ¹H NMR (500 MHz, CDCl₃) δ (ppm): 1.37 (s, 12H), 7.43-7.49 (m, 2H), 7.50-7.57 (m, 3H), 7.81-7.85 (m, 1H), 7.86-7.91 (m, 2H), 8.10-8.14 (m, 1H), 8.15 (dd, J=7.5, 1.5 Hz, 1H), 8.17-8.21 (m, 1H). ¹³C NMR (125 MHz, CDCl₃) δ (ppm): 24.87, 83.88, 120.34, 121.67, 122.58, 124.27, 124.97, 126.66, 127.03, 128.04, 130.87, 134.34, 134.80, 135.79, 136.07, 136.97, 138.63, 139.60, 139.96.

Synthesis of intermediate (Py-Br): a dry flask was charged with o-methoxyphenylboronic acid (3.74 g, 24.62 mmoL, 1.0 equiv), 2,6-dibromopyridine (7.0 g, 29.55 mmoL, 1.2 equiv), tetrakis (triphenylphosphine) palladium (284 mg, 0.25 mmoL, 1 mmoL %), and anhydrous potassium carbonate (6.80 g, 49.24 mmoL, 2.0 equiv). The oil pump was purged with nitrogen three times and deionized water (20 mL) and redistilled 1,4-dioxane (100 mL) were added by injection. After stirring at 70° C. for 72 h, the low boiling point solvent was removed by rotary evaporation under reduced pressure, and then further purified by silica gel chromatography column using petroleum ether/ethyl acetate=200:1-100:1 as eluent, concentrated to give 4.12 g of a colorless liquid in a yield of 63%. ¹H NMR (500 MHz, CDCl₃) δ (ppm): 3.87 (s, 3H), 6.99 (d, J=8.5 Hz, 1H), 7.08 (td, J=7.5, 1.0 Hz, 1H), 7.36-7.40 (m, 2H), 7.54 (t, J=7.5 Hz, 1H), 7.85 (dd, J=7.5, 1.5 Hz, 2H). ¹³C NMR (125 MHz, CDCl₃) δ (ppm): 55.50, 111.32, 121.02, 123.79, 125.74, 127.16, 130.47, 131.23, 137.93, 141.31, 156.84, 156.97.

Synthesis of intermediate (LSZ-OMe): a dry Schlenk tube was charged with SZ-Bpin (500 mg, 1.29 mmoL, 1.0 equiv), Py-Br (340 mg, 1.29 mmoL, 1.0 equiv), tetrakis (triphenylphosphine) palladium (45 mg, 0.039 mmoL, 3 mmoL %) and anhydrous potassium carbonate (357 mg, 2.58 mmoL, 2.0 equiv). The oil pump was purged with nitrogen three times deionized water (1 mL) was injected and 1,4-dioxane (4 mL) was redistilled. After 48 h at 85° C., the low boiling point solvent was removed by rotary evaporation under reduced pressure, and further purified by silica gel chromatography column using petroleum ether/ethyl acetate=100:1-20:1 as eluent, concentrated to give 526 mg of white solid product in a yield of 92%. ¹H NMR (500 MHz, CDCl₃) δ (ppm): 3.90 (s, 3H), 7.02 (dd, J=8.0, 1.0 Hz, 1H), 7.11 (td, J=7.5, 1.0 Hz, 1H), 7.38 (ddd, J=8.0, 7.5, 2.0 Hz, 1H), 7.45-7.50 (m, 2H), 7.58 (s, 1H), 7.59 (d, J=1.5 Hz, 1H), 7.64 (td, J=7.5, 0.5 Hz, 1H), 7.75 (dd, J=7.5, 1.0 Hz, 1H), 7.77-7.82 (m, 2H), 7.83-7.86 (m, 1H), 7.88 (dd, J=7.5, 1.0 Hz, 1H), 8.06 (dd, J=7.5, 2.0 Hz, 1H), 8.17-8.23 (m, 3H), 8.48 (t, J=1.5 Hz, 1H). ¹³C NMR (125 MHz, CDCl₃) δ (ppm): 55.60, 111.45, 118.45, 120.48, 121.06, 121.70, 122.59, 123.69, 124.32, 125.09, 126.68, 126.74, 126.92, 126.94, 128.54, 129.14, 129.90, 131.52, 135.80, 136.21, 136.39, 136.99, 138.69, 139.63, 140.37, 140.88, 155.51, 156.46, 157.23.

Synthesis of ligand (Li): a dry Schlenk tube was charged with LSZ-OMe (500 mg, 1.13 mmoL, 1.0 equiv) and pyridine hydrochloride (1.30 g, 11.27 mmoL, 10 equiv). The oil pump was purged with nitrogen three times and anhydrous 1,3-dimethyl-2-imidazolidinone (4 mL) was added via syringe. The reaction was carried out at 180° C. for 17 h. Ethyl acetate (100 mL) was added, washed with deionized water, and concentrated by rotary evaporation. It was further purified by silica gel column chromatography using petroleum ether/dichloromethane=100:1-10:1 as eluent, concentrated to give 455 mg of white solid product in a yield of 94%. ¹H NMR (500 MHz, DMSO-d₆) δ (ppm): 6.91-6.97 (m, 2H), 7.33 (ddd, J=8.5, 7.0, 1.5 Hz, 1H), 7.60 (dd, J=8.0, 4.0 Hz, 1H), 7.70 (t, J=7.5 Hz, 1H), 7.75 (dd, J=8.0, 7.0 Hz, 1H), 7.81 (dt, J=7.5, 1.5 Hz, 1H), 7.90 (dd, J=7.0, 1.5 Hz, 1H), 8.02-8.04 (m, 2H), 8.08 (ddd, J=10.0, 8.0, 1.5 Hz, 2H), 8.13 (t, J=8.0 Hz, 1H), 8.18-8.25 (m, 1H), 8.28 (t, J=1.5 Hz, 1H), 8.48 (dd, J=8.0, 1.5 Hz, 1H), 8.94 (dd, J=4.0, 2.0 Hz, 1H), 14.41 (s, 1H). ¹³C NMR (125 MHz, CDCl₃) δ (ppm): 117.64, 118.46, 118.78, 118.86, 118.88, 120.70, 121.70, 122.57, 124.38, 125.18, 126.37, 126.41, 126.69, 126.79, 126.90, 129.32, 129.63, 131.52, 135.70, 136.26, 136.32, 138.49, 138.58, 139.41, 141.29, 154.41, 157.75, 159.94. IRMS (ESI): for C₂₉H₂₀NOS [M+H]⁺ calcd 430.1260, found 430.1263.

Synthesis of Pt-1: a dry flask was charged with Li (200 mg, 0.47 mmoL, 1.00 equiv) and platinum dichloride (130 mg, 0.49 mmoL, 1.05 equiv), oil pump was purged with nitrogen three times, and benzonitrile (20 mL) was added by injection, nitrogen bubbling was performed for 30 min to remove oxygen. After stirring at 180° C. for 64 h, the solvent was removed by rotary evaporation under reduced pressure (80° C.), and then further purified by silica gel chromatography column using petroleum ether/dichloromethane=5:1-1:1 as eluent, concentrated to obtain 95 mg of a yellow solid product in a yield of 32%. ¹H NMR (500 MHz, CD₂Cl₂) δ (ppm): 6.66 (ddd, J=8.0, 6.5, 1.5 Hz, 1H), 7.09 (dd, J=8.5, 1.5 Hz, 1H), 7.26 (ddd, J=8.5, 6.5, 1.5 Hz, 1H), 7.37 (t, J=7.5 Hz, 1H), 7.65 (t, J=7.5 Hz, 1H), 7.68 (td, J=7.5, 1.5 Hz, 1H), 7.71-7.77 (m, 4H), 7.80 (dd, J=8.0, 1.5 Hz, 1H), 7.99-8.03 (m, 3H), 8.07 (t, J=7.5 Hz, 1H), 8.22 (ddd, J=8.0, 1.5, 0.5 Hz, 1H), 8.58 (ddd, J=8.0, 1.5, 0.5 Hz, 1H). IRMS (ESI): for C₂₉H₁₈NOPtS [M+H]⁺ calcd 623.0751, found 623.0764.

Example 2: Tetradentate cyclometallated platinum (II) complex phosphorescent light-emitting material Pt-20

The synthetic route is as follows:

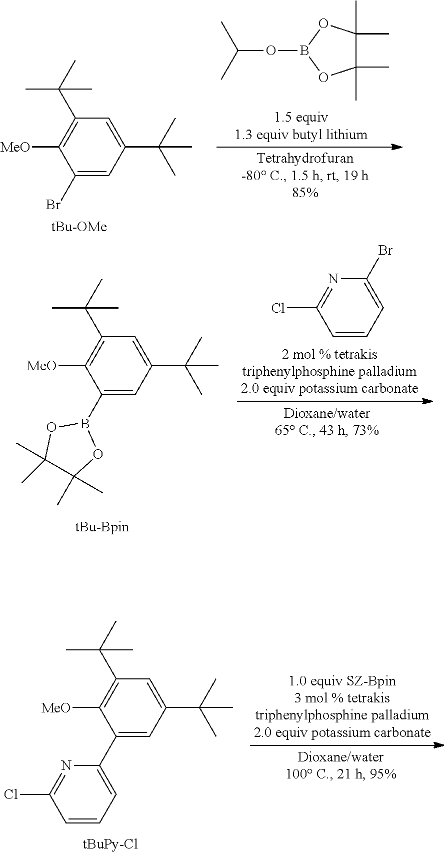 [SMILES: "tBu-OMe" ; COc1c(Br)cc(C(C)(C)C)cc1C(C)(C)C ; CC(C)OB1OC(C)(C)C(C)(C)O1 ; COc1c(B2OC(C)(C)C(C)(C)O2)cc(C(C)(C)C)cc1C(C)(C)C ; Clc1cccc(Br)n1 ; COc1c(-c2cccc(Cl)n2)cc(C(C)(C)C)cc1C(C)(C)C]

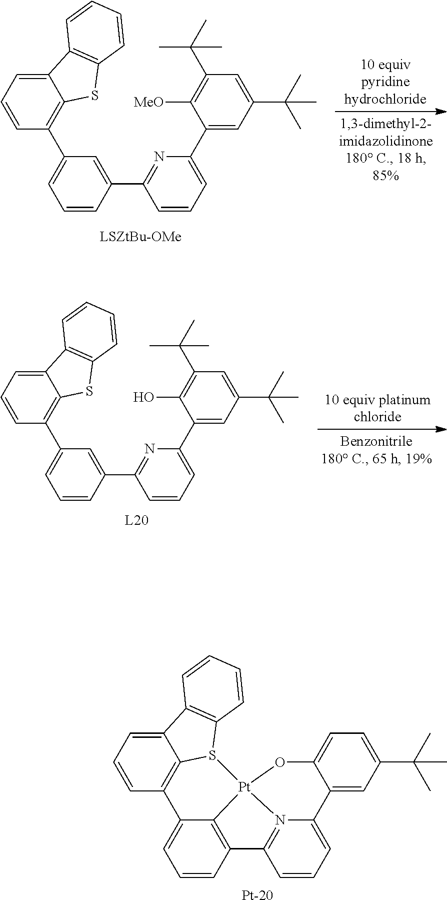

Synthesis of intermediate (tBu-Bpin): a dry flask was charged with tBu-OMe (20.0 g, 66.83 mmoL, 1.0 equiv), oil pump was purged with nitrogen three times, and the redistilled tetrahydrofuran (250 mL) was added via syringe. The reaction flask was placed in an ethanol cooling bath, cooled to −80° C. with liquid nitrogen, and then n-butyllithium (54.30 mL, 86.88 mmoL, 1.3 equiv, 1.60 M in hexane) was slowly added dropwise. After the reaction for 1.5 h, isopropanol pinacolborate (18.65 g, 100 mmoL, 1.5 equiv) was added via a syringe, and the reaction was stirred at room temperature for 19 h. The reaction was quenched by adding aqueous ammonium chloride solution, re-extracted with ethyl acetate three times, and concentrated by rotary evaporation. It was further purified by silica gel column chromatography, using petroleum ether/ethyl acetate=100:1-10:1 as eluent, and concentrated to give 19.68 g of a white solid product in a yield of 85%. ¹H NMR (500 MHz, CDCl₃) δ (ppm): 1.31 (s, 9H), 1.37 (s, 12H), 1.39 (s, 9H), 3.84 (s, 3H), 7.44 (d, J=2.5 Hz, 1H), 7.58 (d, J=2.5 Hz, 1H). 13C NMR (125 MHz, CDCl₃) δ (ppm): 24.78, 30.95, 31.53, 34.39, 35.10, 63.03, 83.49, 127.49, 131.35, 140.87, 144.43, 163.30.

Synthesis of intermediate (tBuPy-Cl): a dry flask was charged with tBu-Bpin (19.68 g, 56.83 mmoL, 1.0 equiv), 2-bromo-6-chloropyridine (13.68 g, 71.07 mmoL, 1.2 equiv), tetrakis (triphenylphosphine) palladium (1.37 g, 1.18 mmoL, 2 mmoL %) and anhydrous potassium carbonate (16.37 g, 118.44 mmoL, 2.0 equiv). The oil pump was purged with nitrogen three times and deionized water (40 mL) and redistilled 1,4-dioxane (220 mL) were added by injection. After reaction at 65° C. for 43 h, the low boiling point solvent was removed by rotary evaporation under reduced pressure, and then further purified by silica gel chromatography column using petroleum ether/dichloromethane=200:1-100:1 as eluent. After concentration, the excess of 2-bromo-6-chloropyridine was separated under reduced pressure and vacuum at an elevated temperature of 150° C. to give 13.69 g of a white solid product in a yield of 73%. ¹H NMR (500 MHz, CDCl₃) δ (ppm): 1.33 (s, 9H), 1.43 (s, 9H), 3.35 (s, 3H), 7.26-7.27 (m, 1H), 7.40 (d, J=2.5 Hz, 1H), 7.46 (d, J=2.5 Hz, 1H), 7.66 (t, J=7.5 Hz, 1H), 7.71 (dd, J=7.5, 1.0 Hz, 1H). ¹³C NMR (125 MHz, CDCl₃) δ (ppm): 30.90, 31.47, 34.61, 35.31, 61.50, 122.02, 123.24, 125.15, 126.50, 131.79, 138.56, 142.07, 145.72, 151.11, 155.58, 158.82.

Synthesis of intermediate (LSZtBu-OMe): a dry Schlenk tube was charged with SZ-Bpin (600 mg, 1.55 mmoL, 1.0 equiv), tBuPy-Cl (567 mg, 1.71 mmoL, 1.1 equiv), tetrakis (triphenylphosphine) palladium (54 mg, 0.047 mmoL, 3 mmoL %), and anhydrous potassium carbonate (429 mg, 3.11 mmoL, 2.0 equiv). The oil pump was purged with nitrogen three times and deionized water (1 mL) was injected and 1,4-dioxane (5 mL) was redistilled. After 21 h at 100° C., the low boiling point solvent was removed by rotary evaporation under reduced pressure, and further purified by silica gel chromatography column using petroleum ether/ethyl acetate=1:1-50:1 as eluent, concentrated to give 820 mg of a white solid product in a yield of 95%. ¹H NMR (500 MHz, DMSO-d₆) δ (ppm): 1.25 (s, 9H), 1.40 (s, 9H), 3.31 (s, 3H), 7.34 (d, J=2.5 Hz, 1H), 7.54-7.56 (m, 2H), 7.60 (d, J=2.5 Hz, 1H), 7.67 (d, J=2.0 Hz, 1H), 7.68 (s, 1H), 7.71-7.76 (m, 2H), 7.81-7.84 (m, 1H), 7.97-8.01 (m, 2H), 8.07 (dd, J=8.0, 1.0 Hz, 1H), 8.26 (dt, J=8.0, 1.5 Hz, 1H), 8.41-8.45 (m, 2H), 8.67 (t, J=2.0 Hz, 1H). ¹³C NMR (125 MHz, CDCl₃) δ (ppm): 30.96, 31.52, 34.62, 35.35, 61.39, 118.28, 120.52, 121.71, 122.65, 123.35, 124.35, 124.60, 125.10, 126.58, 126.74, 126.91, 126.97, 128.68, 129.24, 133.29, 135.82, 136.26, 136.82, 136.97, 138.65, 139.61, 140.07, 140.95, 141.97, 145.52, 155.74, 156.61, 157.88.

Synthesis of ligand (L20): a dry Schlenk tube was charged with LSZtBu-OMe (800 mg, 1.44 mmoL, 1.0 equiv) and pyridine hydrochloride (1.66 g, 14.39 mmoL, 10 equiv). The oil pump was purged with nitrogen three times and anhydrous 1,3-dimethyl-2-imidazolidinone (2 mL) was added via syringe. The reaction was stirred at 180° C. for 18 h, washed with ethyl acetate (100 mL), purified water, and concentrated by rotary evaporation. It was further purified by silica gel column chromatography using petroleum ether/ethyl acetate=100:1-50:1 as eluent, concentrated to give 660 mg of a yellow solid product in a yield of 85% yield. ¹H NMR (500 MHz, DMSO-d₆) δ (ppm): 1.33 (s, 9H), 1.41 (s, 9H), 7.34 (d, J=2.0 Hz, 1H), 7.53-7.57 (m, 2H), 7.66-7.71 (m, 2H), 7.81-7.84 (m, 2H), 7.90 (ddd, J=7.5, 2.0, 1.0 Hz, 1H), 7.97-8.01 (m, 1H), 8.05 (dd, J=7.5, 0.5 Hz, 1H), 8.10 (ddd, J=7.5, 2.0, 1.0 Hz, 1H), 8.14 (t, J=7.5 Hz, 1H), 8.26 (d, J=8.0 Hz, 1H), 8.40 (t, J=2.0 Hz, 1H), 8.41-8.47 (m, 2H), 15.00 (s, 1H). ¹³C NMR (125 MHz, CDCl₃) δ (ppm): 29.68, 31.64, 34.35, 35.38, 118.06, 118.40, 118.46, 120.69, 121.04, 121.69, 122.71, 124.38, 125.15, 126.27, 126.53, 126.77, 126.84, 127.00, 129.26, 129.69, 135.73, 136.33, 136.45, 137.65, 138.35, 138.56, 138.86, 139.53, 139.81, 141.27, 154.18, 156.86, 159.09. HRMS (ESI): for C₃₇H₃₆NOS [M+H]⁺ calcd 542.2512, found 542.2511.

Synthesis of Pt-20: a dry flask was charged with L20 (300 mg, 0.55 mmoL, 1.0 equiv.) and platinum dichloride (147 mg, 0.55 mmoL, 1.0 equiv.), oil pump was purged with nitrogen three times, benzonitrile (25 mL) was added by injection, nitrogen bubbling was performed for 30 min to remove oxygen. After reaction at 180° C. for 65 h, the solvent was removed by rotary evaporation under reduced pressure at 80° C., and then further purified by silica gel chromatography column using petroleum ether/dichloromethane=5:1-1:1 as eluent, concentrated to give 70 mg of a yellow solid product in a yield of 19% yield. ¹H NMR (500 MHz, CD₂Cl₂) δ (ppm): 1.32 (s, 9H), 7.05 (d, J=8.5 Hz, 1H), 7.33-7.37 (m, 2H), 7.63 (t, J=7.5 Hz, 1H), 7.66-7.74 (m, 5H), 7.78 (dd, J=7.5, 1.5 Hz, 1H), 7.98-8.01 (m, 3H), 8.06 (t, J=8.0 Hz, 1H), 8.20 (dd, J=7.5, 1.0 Hz, 1H), 8.59 (ddd, J=7.5, 1.5, 0.5 Hz, 1H). HRMS (ESI): for C₃₃H₂₆NOPtS [M+H]⁺ calcd 679.1378, found 679.1350.

Example 3: The synthesis route of tetradentate cyclometallated platinum (II) complex phosphorescent light-emitting material Pt-3 is as follows:

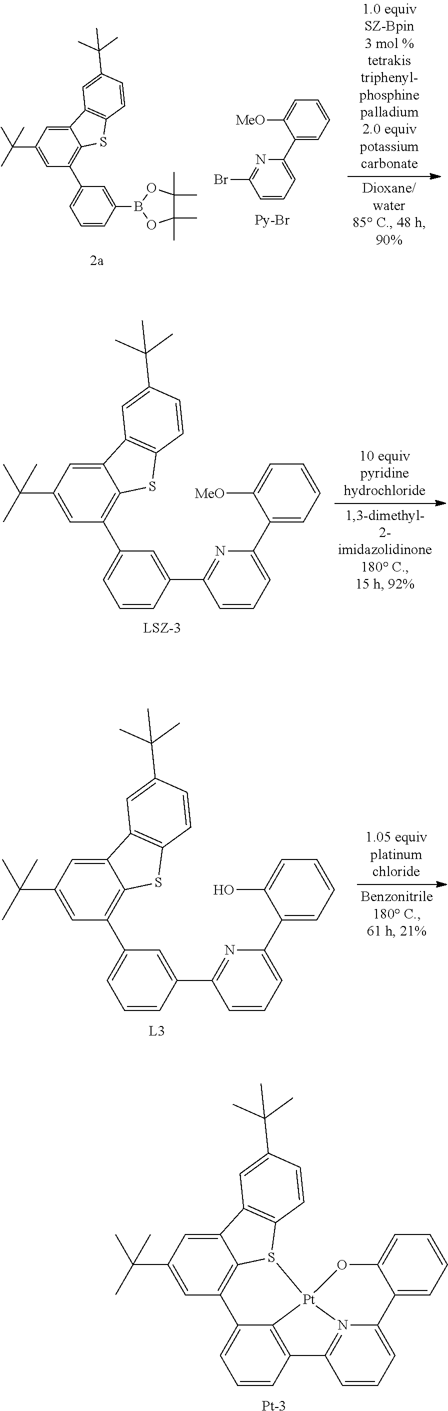

Synthesis of intermediate (LSZ-3): a dry Schlenk tube was charged with 2a (1.0 equiv), Py-Br (1.0 equiv), tetrakis (triphenylphosphine) palladium (3 mmoL %), and anhydrous potassium carbonate (2.0 equiv). The oil pump was purged with nitrogen three times and deionized water (1 mL) was injected and 1,4-dioxane (4 mL) was redistilled. After 48 h at 85° C., the low boiling point solvent was removed by rotary evaporation under reduced pressure and further purified by silica gel chromatography column using petroleum ether/ethyl acetate=100:1-20:1 as eluent to give a white solid product in a yield of 90%.

Synthesis of ligand (L3): a dry Schlenk tube was charged with LSZ-3 (1.0 equiv) and pyridine hydrochloride (10 equiv). The oil pump was purged with nitrogen three times and anhydrous 1,3-dimethyl-2-imidazolidinone (4 mL) was added via syringe. The reaction was stirred at 180° C. for 15 h. Ethyl acetate (100 mL) was added, washed with deionized water, and concentrated by rotary evaporation. Further purification was performed by silica gel chromatography using petroleum ether/dichloromethane=100:1-10:1 as eluent to give a white solid product in a yield of 94%.

Synthesis of Pt-3: a dry flask was charged with L3 (1.00 equiv) and platinum dichloride (1.05 equiv), oil pump was purged with nitrogen three times, and benzonitrile (20 mL) was added by injection, nitrogen bubbling was performed for 30 min to remove oxygen. After stirring at 180° C. for 61 h, the solvent was removed by rotary evaporation under reduced pressure, and then further purified by silica gel chromatography column using petroleum ether/dichloromethane=5:1-1:1 as eluent to give a yellow solid product in a yield of about 21%. MS: m/z 735.19 (M+H)⁺.

Example 4: The synthesis route of tetradentate cyclometallated platinum (II) complex phosphorescent light-emitting material Pt-131 is as follows:

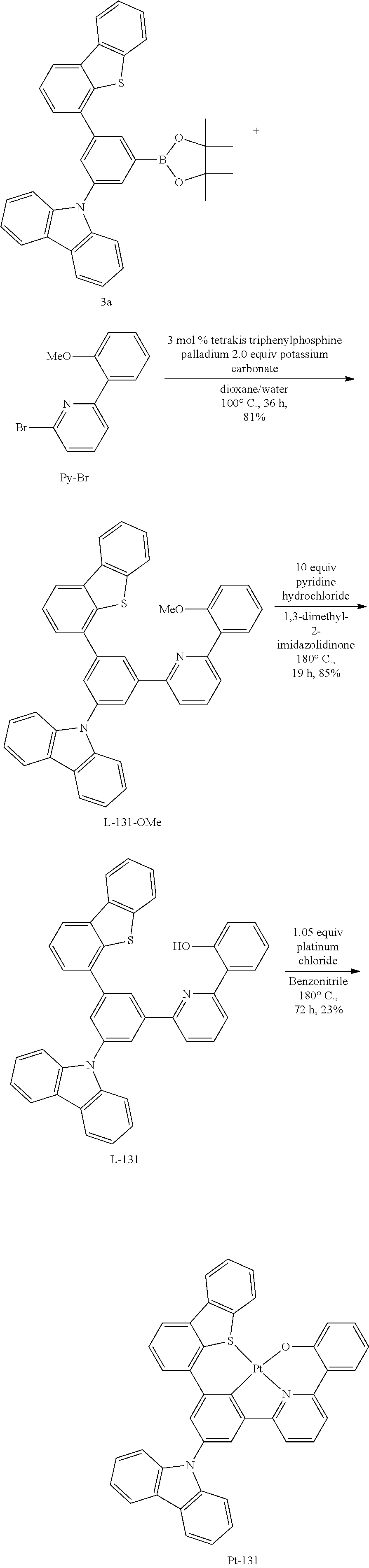

Synthesis of intermediate (L131-OMe): a Schlenk tube with a magnetic stir bar was charged with 3a (1.0 equiv), py-Br (1.3 equiv), tetrakis triphenylphosphine palladium (3 mol %) and potassium carbonate (2.0 equiv). The nitrogen was then purged three times and 1,4-dioxane (8 mL) and water (2 mL) were added under nitrogen. After 30 h of reaction in an oil bath kettle at 100° C., cooling to room temperature, distilling off the solvent under reduced pressure, and then separating the crude product with a silica gel chromatography column, the eluent: petroleum ether/ethyl acetate=20:1-10:1 to give a yellow solid in a yield of about 81%.

Synthesis of ligand L-131: a Schlenk tube with a stir bar was charged with L-131 (1.0 equiv), and pyridine hydrochloride (10.0 equiv). The nitrogen was then purged three times and 1,3-dimethyl-2-imidazolidinone (3 mL) was added under nitrogen. After 17 h of reaction in an oil bath kettle at 180° C., cooling to room temperature, diluting by adding ethyl acetate, washing the organic phase with water, separating the layers, drying over anhydrous sodium sulfate, filtering, and distilling the filtrate under reduced pressure to remove the solvent. The crude product was separated on a silica gel column, eluent: petroleum ether/ethyl acetate=20:1-5:1 to give a white solid in a yield of about 85%.

Synthesis of Pt-131: a three-neck flask with a magnetic stir bar was charged with L-131 (1.0 equiv) and platinum dichloride (1.05 equiv), the oil pump was purged with nitrogen three times, and benzonitrile (20 mL) was added by injection, and nitrogen bubbling was performed for 30 min to remove oxygen. After stirring at 180° C. for 64 h, the solvent was removed by rotary evaporation under reduced pressure, and then further purified by silica gel chromatography column using petroleum ether/dichloromethane=5:1-1:1 as eluent to give a yellow solid product in a yield of about 32%. MS: m/z 788.13 (M+H)⁺.

Example 5: Tetradentate cyclometallated platinum (II) complex phosphorescent light-emitting material Pt-2

Pt-2 was synthesized by referring to the synthesis mode of Example 1, which only differs from Example 1 in that the target compound Pt-2, a yellow solid, was synthesized by replacing the ligand starting material of the corresponding fragment in Example 1. MS: m/z 651.10 (M+H)⁺.

Example 6: Tetradentate cyclometallated platinum (II) complex phosphorescent light-emitting material Pt-4

Pt-4 was synthesized by referring to the synthesis mode of Example 1, which only differs from Example 1 in that the target compound Pt-4, a yellow solid, was synthesized by replacing the ligand starting material of the corresponding fragment in Example 1. MS: m/z 775.13 (M+H)⁺.

Example 7: Tetradentate cyclometallated platinum (II) complex phosphorescent light-emitting material Pt-15

Pt-15 was synthesized by referring to the synthesis mode of Example 1, which only differs from Example 1 in that the target compound Pt-15, a yellow solid, was synthesized by replacing the ligand starting material of the corresponding fragment in Example 1. MS: m/z 785.18 (M+H)⁺.

Example 8: Tetradentate cyclometallated platinum (II) complex phosphorescent light-emitting material Pt-22

Pt-22 was synthesized with reference to the synthesis mode of Example 1, except that the target compound Pt-22 was synthesized by replacing the ligand starting material of the corresponding fragment in Example 1. Yellow solid. MS: m/z 792.15 (M+H)⁺.

Example 9: Tetradentate cyclometallated platinum (II) complex phosphorescent light-emitting material Pt-26

Pt-26 was synthesized by referring to the synthesis mode of Example 1, which only differs from Example 1 in that the target compound Pt-26, a yellow solid, was synthesized by replacing the ligand starting material of the corresponding fragment in Example 1. MS: m/z 755.16 (M+H)⁺.

Example 10: Tetradentate cyclometallated platinum (II) complex phosphorescent light-emitting material Pt-29

Pt-29 was synthesized with reference to the synthesis mode of Example 1, except that the target compound Pt-29 was synthesized by replacing the ligand starting material of the corresponding fragment in Example 1. Yellow solid. MS: m/z 711.13 (M+H)⁺.

Example 11: Tetradentate cyclometallated platinum (II) complex phosphorescent light-emitting material Pt-30

Pt-30 was synthesized by referring to the synthesis mode of Example 1, which only differs from Example 1 in that the target compound Pt-30, a yellow solid, was synthesized by replacing the ligand starting material of the corresponding fragment in Example 1. MS: m/z 699.10 (M+H)⁺.

Example 12: Tetradentate cyclometallated platinum (II) complex phosphorescent light-emitting material Pt-31

Pt-31 was synthesized by referring to the synthesis mode of Example 1, which only differs from Example 1 in that the target compound Pt-31, a yellow solid, was synthesized by replacing the ligand starting material of the corresponding fragment in Example 1. MS: m/z 673.08 (M+H)⁺.

Example 13: Tetradentate cyclometallated platinum (II) complex phosphorescent light-emitting material Pt-49

Pt-49 was synthesized by referring to the synthesis mode of Example 1, which only differs from Example 1 in that the target compound Pt-49, a yellow solid, was synthesized by replacing the ligand starting material of the corresponding fragment in Example 1. MS: m/z 831.19 (M+H)⁺.

Example 14: Tetradentate cyclometallated platinum (II) complex phosphorescent light-emitting material Pt-55

Pt-55 was synthesized with reference to the synthesis mode of Example 1, except that the target compound Pt-55 was synthesized by replacing the ligand starting material of the corresponding fragment in Example 1. Yellow solid. MS: m/z 750.09 (M+H)⁺.

Example 15: Tetradentate cyclometallated platinum (II) complex phosphorescent light-emitting material Pt-58

Pt-58 was synthesized with reference to the synthesis mode of Example 1, except that the target compound Pt-58 was synthesized by replacing the ligand starting material of the corresponding fragment in Example 1. Yellow solid. MS: m/z 733.18 (M+H)⁺.

Example 16: Tetradentate cyclometallated platinum (II) complex phosphorescent light-emitting material Pt-60

Pt-60 was synthesized with reference to the synthesis mode of Example 1, except that the target compound Pt-60 was synthesized by replacing the ligand starting material of the corresponding fragment in Example 1. Yellow solid. MS: m/z 841.21 (M+H)⁺.

Example 17: Tetradentate cyclometallated platinum (II) complex phosphorescent light-emitting material Pt-63

Pt-63 was synthesized with reference to the synthesis mode of Example 1, except that the target compound Pt-63 was synthesized by replacing the ligand starting material of the corresponding fragment in Example 1. Yellow solid. MS: m/z 681.14 (M+H)⁺.

Example 18: Tetradentate cyclometallated platinum (II) complex phosphorescent light-emitting material Pt-67

Pt-67 was synthesized with reference to the synthesis mode of Example 1, except that the target compound Pt-67 was synthesized by replacing the ligand starting material of the corresponding fragment in Example 1. Yellow solid. MS: m/z 757.18 (M+H)⁺.

Example 19: Tetradentate cyclometallated platinum (II) complex phosphorescent light-emitting material Pt-71

Pt-71 was synthesized with reference to the synthesis mode of Example 1, except that the target compound Pt-71 was synthesized by replacing the ligand starting material of the corresponding fragment in Example 1. Yellow solid. MS: m/z 719.17 (M+H)⁺.

Example 20: Tetradentate cyclometallated platinum (II) complex phosphorescent light-emitting material Pt-73

Pt-73 was synthesized with reference to the synthesis mode of Example 1, except that the target compound Pt-73 was synthesized by replacing the ligand starting material of the corresponding fragment in Example 1. Yellow solid. MS: m/z 857.31 (M+H)⁺.

Example 21: Tetradentate cyclometallated platinum (II) complex phosphorescent light-emitting material Pt-77

Pt-77 was synthesized with reference to the synthesis mode of Example 1, except that the target compound Pt-77 was synthesized by replacing the ligand starting material of the corresponding fragment in Example 1. Yellow solid. MS: m/z 768.15 (M+H)⁺.

Example 22: Tetradentate cyclometallated platinum (II) complex phosphorescent light-emitting material Pt-80

Pt-80 was synthesized with reference to the synthesis mode of Example 1, except that the target compound Pt-80 was synthesized by replacing the ligand starting material of the corresponding fragment in Example 1. Yellow solid. MS: m/z 737.19 (M+H)⁺.

Example 23: Tetradentate cyclometallated platinum (II) complex phosphorescent light-emitting material Pt-82

Pt-82 was synthesized with reference to the synthesis mode of Example 1, except that the target compound Pt-82 was synthesized by replacing the ligand starting material of the corresponding fragment in Example 1. Yellow solid. MS: m/z 831.20 (M+H)⁺.

Example 24: Tetradentate cyclometallated platinum (II) complex phosphorescent light-emitting material Pt-93

Pt-93 was synthesized by referring to the synthesis mode of Example 1, which only differs from Example 1 in that the target compound Pt-93, a yellow solid, was synthesized by replacing the ligand starting material of the corresponding fragment in Example 1. MS: m/z 791.93 (M+H)⁺.

Example 25: Tetradentate cyclometallated platinum (II) complex phosphorescent light-emitting material Pt-94

Pt-94 was synthesized by referring to the synthesis mode of Example 1, which only differs from Example 1 in that the target compound Pt-94, a yellow solid, was synthesized by replacing the ligand starting material of the corresponding fragment in Example 1. MS: m/z 811.22 (M+H)⁺.

Example 26: Tetradentate cyclometallated platinum (II) complex phosphorescent light-emitting material Pt-98

Pt-98 was synthesized by referring to the synthesis mode of Example 1, which only differs from Example 1 in that the target compound Pt-98, a yellow solid, was synthesized by replacing the ligand starting material of the corresponding fragment in Example 1. MS: m/z 769.79 (M+H)⁺.

Example 27: Tetradentate cyclometallated platinum (II) complex phosphorescent light-emitting material Pt-103

Pt-103 was synthesized with reference to the synthesis mode of Example 1, except that the target compound Pt-103 was synthesized by replacing the ligand starting material of the corresponding fragment in Example 1. Yellow solid. MS: m/z 713.08 (M+H)⁺.

Example 28: Tetradentate cyclometallated platinum (II) complex phosphorescent light-emitting material Pt-108

Pt-108 was synthesized by referring to the synthesis mode of Example 1, which only differs from Example 1 in that the target compound Pt-108, a yellow solid, was synthesized by replacing the ligand starting material of the corresponding fragment in Example 1. MS: m/z 795.19 (M+H)⁺.

Example 29: Tetradentate cyclometallated platinum (II) complex phosphorescent light-emitting material Pt-114

Pt-114 was synthesized with reference to the synthesis mode of Example 1, except that the target compound Pt-114 was synthesized by replacing the ligand starting material of the corresponding fragment in Example 1. Yellow solid. MS: m/z 851.26 (M+H)⁺.

Example 30: Tetradentate cyclometallated platinum (II) complex phosphorescent light-emitting material Pt-122

Pt-122 was synthesized by referring to the synthesis mode of Example 1, which only differs from Example 1 in that the target compound Pt-122, a yellow solid, was synthesized by replacing the ligand starting material of the corresponding fragment in Example 1. MS: m/z 920.22 (M+H)⁺.

Example 31: Tetradentate cyclometallated platinum (II) complex phosphorescent light-emitting material Pt-123

Pt-123 was synthesized by referring to the synthesis mode of Example 1, which only differs from Example 1 in that the target compound Pt-123, a yellow solid, was synthesized by replacing the ligand starting material of the corresponding fragment in Example 1. MS: m/z 920.22 (M+H)⁺.

Example 32: Tetradentate cyclometallated platinum (II) complex phosphorescent light-emitting material Pt-125

Pt-125 was synthesized by referring to the synthesis mode of Example 1, which only differs from Example 1 in that the target compound Pt-125, a yellow solid, was synthesized by replacing the ligand starting material of the corresponding fragment in Example 1. MS: m/z 952.19 (M+H)⁺.

Example 33: Tetradentate cyclometallated platinum (II) complex phosphorescent light-emitting material Pt-129

Pt-129 was synthesized with reference to the synthesis mode of Example 1, except that the target compound Pt-129 was synthesized by replacing the ligand starting material of the corresponding fragment in Example 1. Yellow solid. MS: m/z 922.24 (M+H)⁺.

Example 34: Tetradentate cyclometallated platinum (II) complex phosphorescent light-emitting material Pt-130

Pt-130 was synthesized by referring to the synthesis mode of Example 1, which only differs from Example 1 in that the target compound Pt-130, a yellow solid, was synthesized by replacing the ligand starting material of the corresponding fragment in Example 1. MS: m/z 962.27 (M+H)⁺.

Example 35: Tetradentate cyclometallated platinum (II) complex phosphorescent light-emitting material Pt-131

Pt-131 was synthesized with reference to the synthesis mode of Example 1, except that the target compound Pt-131 was synthesized by replacing the ligand starting material of the corresponding fragment in Example 1. Yellow solid. MS: m/z 788.13 (M+H)⁺.

Example 36: Tetradentate cyclometallated platinum (II) complex phosphorescent light-emitting material Pt-135

Pt-135 was synthesized with reference to the synthesis mode of Example 1, except that the target compound Pt-135 was synthesized by replacing the ligand starting material of the corresponding fragment in Example 1. Yellow solid. MS: m/z 799.19 (M+H)⁺.

Example 37: Tetradentate cyclometallated platinum (II) complex phosphorescent light-emitting material Pt-139

Pt-139 was synthesized with reference to the synthesis mode of Example 1, except that the target compound Pt-139 was synthesized by replacing the ligand starting material of the corresponding fragment in Example 1. Yellow solid. MS: m/z 881.16 (M+H)⁺.

Example 38: Tetradentate cyclometallated platinum (II) complex phosphorescent light-emitting material Pt-145

Pt-145 was synthesized with reference to the synthesis mode of Example 1, except that the target compound Pt-145 was synthesized by replacing the ligand starting material of the corresponding fragment in Example 1. Yellow solid. MS: m/z 1015.21 (M+H)⁺.

Example 39: Tetradentate cyclometallated platinum (II) complex phosphorescent light-emitting material Pt-151

Pt-151 was synthesized with reference to the synthesis mode of Example 1, except that the target compound Pt-151 was synthesized by replacing the ligand starting material of the corresponding fragment in Example 1. Yellow solid. MS: m/z 828.27 (M+H)⁺.

Example 40: Tetradentate cyclometallated platinum (II) complex phosphorescent light-emitting material Pt-153

Pt-153 was synthesized with reference to the synthesis mode of Example 1, except that the target compound Pt-153 was synthesized by replacing the ligand starting material of the corresponding fragment in Example 1. Yellow solid. MS: m/z 875.36 (M+H)⁺.

Example 41: Tetradentate cyclometallated platinum (II) complex phosphorescent light-emitting material Pt-155

Pt-155 was synthesized with reference to the synthesis mode of Example 1, except that the target compound Pt-155 was synthesized by replacing the ligand starting material of the corresponding fragment in Example 1. Yellow solid. MS: m/z 941.47 (M+H)⁺.

Example 42: The synthesis route of tetradentate cyclometallated palladium (II) complex phosphorescent light-emitting material Pd-156 is as follows:

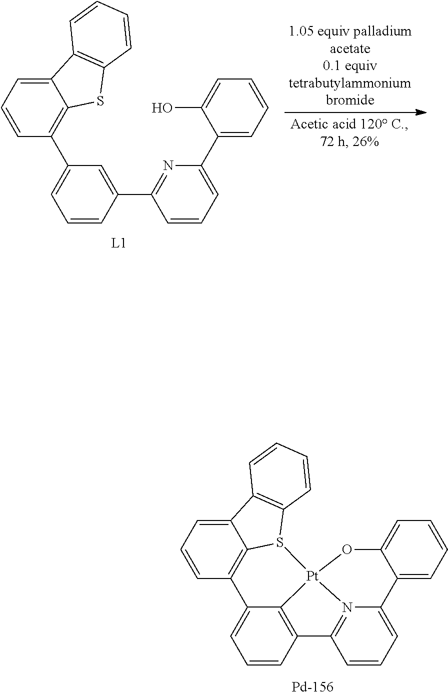

Synthesis of Pd-156: L-1 (1.0 equiv), palladium acetate (1.05 equiv), and tetrabutylammonium bromide (0.1 equiv) were charged to a three-neck flask equipped with a magnetic stir bar, nitrogen was purged three times, acetic acid (20 mL) was added under nitrogen and nitrogen bubbling was performed for 30 min to remove oxygen. The three-necked bottle was placed into an oil bath kettle with magnetic stirring, and heated at 120° C. for 72 h, the reaction was cooled to room temperature, the solvent was distilled off under reduced pressure; and the obtained crude product was separated with a silica gel chromatography column, with an eluent: petroleum ether/dichloromethane=5:1-1:1 to give a yellow solid in a yield of 26%. MS: m/z 534.01 (M+H)⁺.

Example 43: Tetradentate cyclometallated platinum (II) complex phosphorescent light-emitting material Pt-165

With reference to Example 1, the synthesis method of Example 42 synthesizes Pt-165, which differs from Example 1 only in that the ligand raw material of the corresponding fragment in Example 1 is replaced, and the target compound Pt-165 can be synthesized after metallization with reference to an example. Yellow solid. MS: m/z 590.07 (M+H)⁺.

Example 44: Tetradentate cyclometallated platinum (II) complex phosphorescent light-emitting material Pt-166

With reference to Example 1, the synthesis mode of example synthesizes Pt-166, which differs from Example 1 only in that the ligand raw material of the corresponding fragment in Example 1 is replaced, and the target compound Pt-166 can be synthesized after metallation with reference to example. Yellow solid. MS: m/z 693.12 (M+H)⁺.

Example 45: Tetradentate cyclometallated platinum (II) complex phosphorescent light-emitting material Pt-171

With reference to Example 1, the synthesis mode of example synthesizes Pt-171, which only differs from Example 1 in that the ligand raw material of the corresponding fragment in Example 1 is replaced, and the target compound Pd-171, a yellow solid, can be synthesized after metallation with reference to the example. MS: m/z 590.07 (M+H)⁺.

Example 46: Tetradentate cyclometallated platinum (II) complex phosphorescent light-emitting material Pt-184

With reference to Example 1, the synthesis mode of example synthesizes Pt-184, which differs from Example 1 only in that the ligand raw material of the corresponding fragment in Example 1 is replaced, and the target compound Pt-184 can be synthesized after metallation with reference to example. Yellow solid. MS: m/z 847.16 (M+H)⁺.

Example 47: Tetradentate cyclometallated platinum (II) complex phosphorescent light-emitting material Pt-188

With reference to Example 1, the synthesis mode of example synthesizes Pt-188, which differs from Example 1 only in that the ligand raw material of the corresponding fragment in Example 1 is replaced, and the target compound Pt-188 can be synthesized after metallation with reference to example. Yellow solid. MS: m/z 861.21 (M+H)⁺.

Example 48: Tetradentate cyclometallated platinum (II) complex phosphorescent light-emitting material Pt-193

With reference to Example 1, the synthesis mode of example synthesizes Pt-193, which only differs from Example 1 in that the ligand raw material of the corresponding fragment in Example 1 is replaced, and the target compound Pd-193, a yellow solid, can be synthesized after metallation with reference to the example. MS: m/z 584.02 (M+H)⁺.

Example 49: Tetradentate cyclometallated platinum (II) complex phosphorescent light-emitting material Pt-195

With reference to Example 1, the synthesis mode of example synthesizes Pt-195, which only differs from Example 1 in that the ligand raw material of the corresponding fragment in Example 1 is replaced, and the target compound Pd-195, a yellow solid, can be synthesized after metallation with reference to the example. MS: m/z 665.10 (M+H)⁺.

Example 50: Preparation of temperature-responsive doping solutions

1 mg of the complex Pt-20 was placed in a glass tube, 10 mL of toluene solution was added, evenly dissolving after ultrasonication, nitrogen bubbling was performed for 20 min to remove oxygen, and then sealed to isolate oxygen to obtain a temperature-responsive doping solution.

Example 51: Device examples All materials were purified by gradient heating sublimation under a high vacuum (10-5-10-6 Torr) before use. The indium tin oxide (ITO) substrates used for the devices were sonicated sequentially in deionized water, acetone, and isopropanol. The devices were prepared by vacuum thermal evaporation at a vacuum of less than 10⁴ Torr. The anode electrode was indium tin oxide (ITO) with a thickness of 1300 Å, and the cathode was composed of Li₂CO₃ with a thickness of 10 Å and Al with a thickness of 1000 Å. All devices were sealed in a nitrogen glove box with a glass lid and epoxy, and moisture absorbent was added to the package. The light-emitting materials Pt-1 and Pt-20 were used as light-emitting materials to prepare device structures with different host materials and transport materials. The device and electron emission characteristics are shown in Table 1.
Device 1: ITO/HATCN (10 nm)/TAPC (60 nm)/mCBP:PPT:Pt-1 (1:1, 5%, 30 nm)/PPT (2 nm)/Bepp2:Li₂CO₃ (5%, 35 nm)/Li₂CO₃ (1 nm)/Al;
Device 2: ITO/HATCN (10 nm)/TAPC (60 nm)/mCBP:PPT:Pt-1 (1:2, 5%, 30 nm)/PPT (2 nm)/Bepp2:Li₂CO₃ (5%, 35 nm)/Li₂CO₃ (1 nm)/Al;
Device 3: ITO/HATCN (10 nm)/TAPC (60 nm)/DPEPO:Pt-1 (5%, 30 nm)/PPT (2 nm)/PPT:Li₂CO₃ (5%, 35 nm)/Li₂CO₃ (1 nm)/Al;
Device 4: ITO/HATCN (10 nm)/TAPC (60 nm)/mCBP:PPT:Pt-20 (1:1, 5%, 30 nm)/PPT (2 nm)/Bepp2:Li₂CO₃ (5%, 35 nm)/Li₂CO₃ (1 nm)/Al;
Device 5: ITO/HATCN (10 nm)/TAPC (60 nm)/mCBP:Pt-20 (5%, 30 nm)/PPT (2 nm)/Bepp2:Li₂CO₃ (5%, 35 nm)/Li₂CO₃ (1 nm)/Al;
Device 6: ITO/HATCN (10 nm)/TAPC (60 nm)/DPEPO:Pt-20 (1:1, 10%, 30 nm)/PPT (2 nm)/PPT:Li₂CO₃ (5%, 35 nm)/Li₂CO₃ (1 nm)/Al;
Device 7: ITO/HATCN (10 nm)/TAPC (60 nm)/mCBP:PPT:Pt-3 (1:1, 5%, 30 nm)/PPT (2 nm)/Bepp2:Li₂CO₃ (5%, 35 nm)/Li₂CO₃ (1 nm)/Al;
Device 8: ITO/HATCN (10 nm)/TAPC (60 nm)/mCBP:PPT:Pt-95 (1:1, 5%, 30 nm)/PPT (2 nm)/Bepp2:Li₂CO₃ (5%, 35 nm)/Li₂CO₃ (1 nm)/Al;
Device 9: ITO/HATCN (10 nm)/TAPC (60 nm)/mCBP:PPT:Pt-96 (1:1, 5%, 30 nm)/PPT (2 nm)/Bepp2:Li₂CO₃ (5%, 35 nm)/Li₂CO₃ (1 nm)/Al;
Device 10: ITO/HATCN (10 nm)/TAPC (60 nm)/mCBP:PPT:Pt-97 (1:1, 5%, 30 nm)/PPT (2 nm)/Bepp2:Li₂CO₃ (5%, 35 nm)/Li₂CO₃ (1 nm)/Al;
Device 11: ITO/HATCN (10 nm)/TAPC (60 nm)/mCBP:PPT:Pt-107 (1:1, 5%, 30 nm)/PPT (2 nm)/Bepp2:Li₂CO₃ (5%, 35 nm)/Li₂CO₃ (1 nm)/Al;
Device 12: ITO/HATCN (10 nm)/TAPC (60 nm)/mCBP:PPT:Pt-123 (1:1, 5%, 30 nm)/PPT (2 nm)/Bepp2:Li₂CO₃ (5%, 35 nm)/Li₂CO₃ (1 nm)/Al;
Device 13: ITO/HATCN (10 nm)/TAPC (60 nm)/mCBP:PPT:Pt-132 (1:1, 5%, 30 nm)/PPT (2 nm)/Bepp2:Li₂CO₃ (5%, 35 nm)/Li₂CO₃ (1 nm)/Al;
Device 14: ITO/HATCN (10 nm)/TAPC (60 nm)/mCBP:PPT:Pt-150 (1:1, 5%, 30 nm)/PPT (2 nm)/Bepp2:Li₂CO₃ (5%, 35 nm)/Li₂CO₃ (1 nm)/Al;
Device 15: ITO/HATCN (10 nm)/TAPC (60 nm)/mCBP:PPT:Pt-153 (1:1, 5, 30 nm)/PPT (2 nm)/Bepp2:Li₂CO₃ (5, 35 nm)/Li₂CO₃ (1 nm)/Al;

The molecular structures of the materials used in the above devices are shown below:

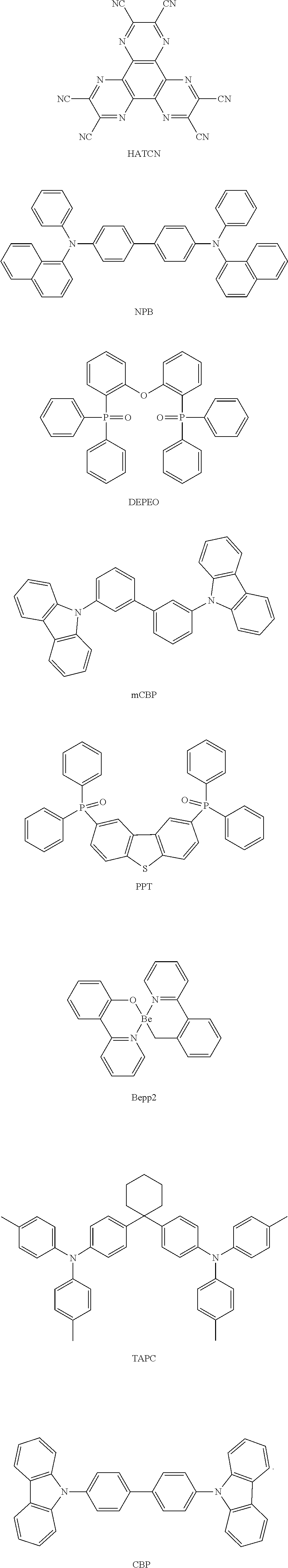

TABLE 1
Device and electron luminescence properties table

| | | Maximum | |
|---|---|---|---|
| | | external | Drive Voltage |
| | | quantum | (Volts)@10 |
| Examples | Device structure | efficiency/% | mA/cm² |
| Device example 1 | Device structure 1 | 15 | 3.2 |
| Device example 2 | Device structure 1 | 11 | 3.3 |
| Device example 3 | Device structure 2 | 12 | 3.1 |
| Device example 4 | Device structure 2 | 10 | 3.3 |
| Device example 5 | Device structure 3 | 14 | 3.2 |
| Device example 6 | Device structure 3 | 13 | 3.4 |
| Device example 7 | Device structure 4 | 13 | 3.5 |
| Device example 8 | Device structure 4 | 15 | 2.9 |
| Device example 9 | Device structure 5 | 9 | 3.2 |
| Device example 10 | Device structure 5 | 10 | 3.3 |
| Device example 11 | Device structure 6 | 12 | 3.3 |
| Device example 12 | Device structure 6 | 10 | 3.3 |
| Device example 13 | Device structure 7 | 12 | 3.1 |
| Device example 14 | Device structure 8 | 13 | 3.4 |
| Device example 15 | Device structure 9 | 11 | 3.2 |
| Device example 16 | Device structure 10 | 16 | 2.8 |
| Device example 17 | Device structure 11 | 14 | 3.1 |
| Device example 18 | Device structure 12 | 12 | 3.3 |
| Device example 19 | Device structure 13 | 13 | 3.0 |
| Device example 20 | Device structure 14 | 15 | 3.3 |
| Device example 21 | Device structure 15 | 13 | 3.1 |

As can be seen from Table 1, the compounds disclosed in the present invention can be used as a light-emitting material for preparing an organic electroluminescent device, and have a certain commercial application value.

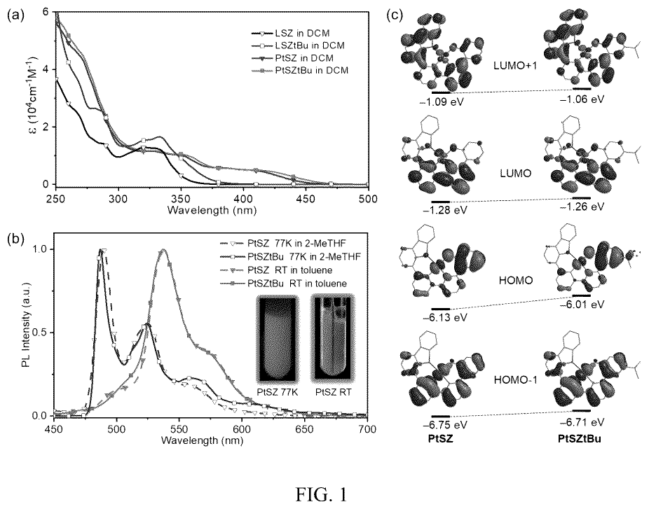

FIG. 1 is a spectrogram of complexes Pt-1 (PtSZ) and Pt-20 (PtSZtBu) and their ligands LSZ and LSZtBu; wherein (a) is the absorption spectrum in dichloromethane, (b) is the PL spectrum in a toluene solution of 2-methyltetrahydrofuran (2-MeTHF) and RT (room temperature) at 77 K; (c) is the theoretically calculated frontier orbital distribution and energy level. As can be seen from FIG. 1, both Pt-1 (PtSZ) and Pt-20 (PtSZtBu) show the same three emission bands in the emission spectra at 77 K and 298 K, and these complexes show different emission behavior in two different temperature ranges.

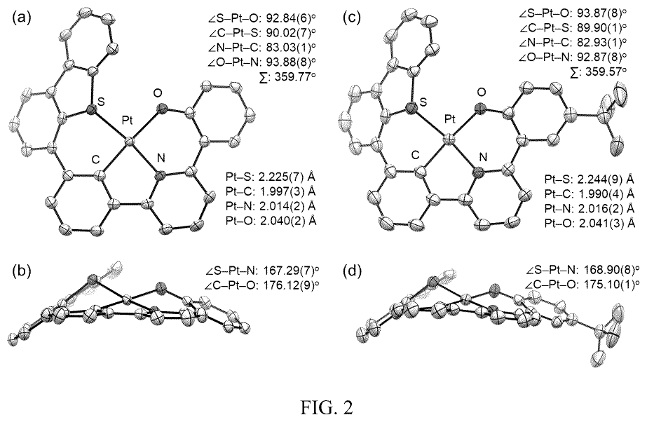

FIG. 2 is a single crystal structure of complexes Pt-1 and Pt-20; as can be seen from FIG. 2, the structures of Pt-1 and Pt-20 were confirmed by X-ray single crystal diffraction analysis. Pt-1 and Pt-20 exhibit highly distorted molecular structures, illustrated by the dihedral angles between the dibenzothiophene and phenol planes of 61.39° and 57.84°, respectively. However, the tetradentate ligands provide rigidity, maintaining square planar coordination of the Pt (II) metal center with four bond angles and almost up to 360°. Notably, the length of the S-Pt bond in Pt-1 (2.225 Å) and Pt-20 (2.244 Å) is similar to the distance in the literature and significantly longer than the previously reported N—Pt (2.040-2.048 Å) due to the larger radius of the S atom.

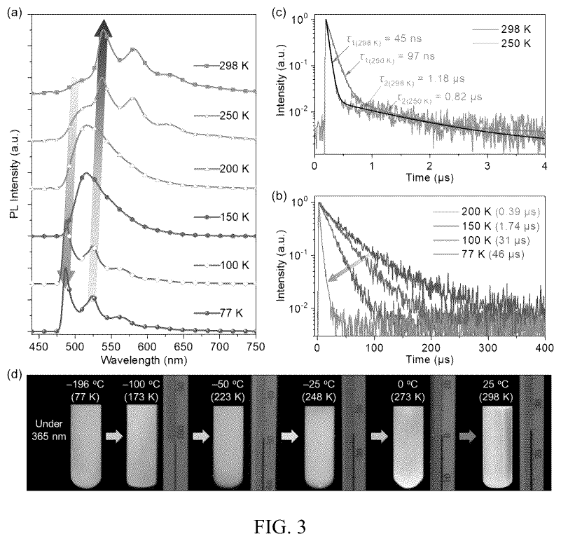

FIG. 3 is a spectrogram of complex Pt-20 in tetrahydrofuran solution; in the figure, (a) is a photoluminescence spectrogram at varying temperatures, (b), (c) are transient spectra, and (d) is the change in luminescence color during the temperature increase in toluene solution. As can be seen from FIG. 3, at 77 K, the main emission peak is quite intense compared to the second and third emission bands, exhibiting cyan luminescence. However, as the temperature increased to 289 K, the main emission peak at 77 K (487 nm) gradually decreased and red-shifted to 509 nm. At the same time, the emission sideband at 524 nm is significantly enhanced and begins to dominate emission, reaching a peak at 539 nm at 298 K, showing yellow luminescence. Each corresponding emission band peak is regularly red-shifted by about 10-12 nm at 298 K compared to the 77 K spectrum. From 77 to 200 K, the transient decay spectra of PtSZtBu in dilute 2-MeTHF solutions show a mono-exponential decay with a gradual decrease in excited state lifetime (τ) from 46 μs to 0.39 μs. However, at 250 and 298 K, PtSZtBu exhibits a bi-exponential decay with a short τ of 45 ns and a relatively long τ of 1.2 μs at 250 K. This phenomenon is caused by different structural deformation of the excited state at different temperatures. The results show that the tetradentate Pt (II)/Pd (II) complexes based on dibenzothiophene coordination have temperature-responsive properties, and can be used in the fields of biomarker, imaging, anti-counterfeiting and temperature sensing. From the change of luminescence color at different temperatures in FIG. (d), it can be seen that as the temperature increases, the luminescence color changes from cyan to green and then to yellow, indicating that it has a temperature response characteristic, and can be used in the fields of optical temperature sensing, etc.

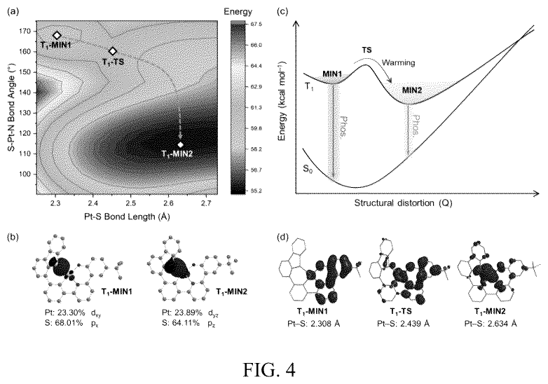

FIG. 4 is a theoretical calculation graph of the complex Pt-20; in the diagram, (a) is the energy diagram of the excited triplet state, (b) is the localized molecular orbital of the Pipek-Mezey localization of the Pt—S bond, (c) is the potential energy curve and optical transition of the triplet emission state (T1), and (d) is the spin density distribution of T1-MIN1/T1-TS/T1-MIN2. As can be seen from FIG. 4, the color change of the emitted light of Pt-20 at different temperatures is caused by the change of the spatial structure caused by the change of its S-Pt bond properties. From this, it can be concluded that the complexes with the same parent and containing such S-Pt all have similar luminescence color changes. Such complexes provided are useful for the preparation of temperature-indicating devices.

It will be understood by those skilled in the art that the embodiments described above are specific examples for practicing the invention, and that various changes in form and details may be made therein without departing from the spirit and scope of the invention. For example, many of the substituent structures described herein can be replaced with other structures without departing from the spirit of the invention.

What is claimed is:

1. A bivalent platinum or palladium metal complex phosphorescent material based on dibenzothiophene coordination, having a general structure shown in Formula (I): 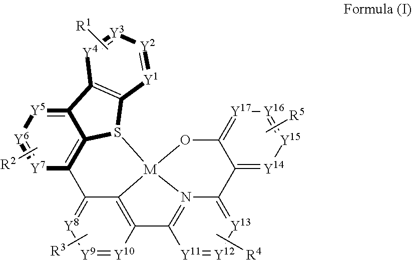
wherein: M is Pt or Pd;
Y¹-Y¹⁷ are each independently selected from N or C atoms;
R¹, R², R³, R⁴, and R⁵ can be each independently mono-, di-, tri-, tetra- or unsubstituted;
R¹, R² are each independently represented by any one of hydrogen, deuterium, halogen, —CN, substituted or unsubstituted C1-C24 alkyl, substituted or unsubstituted C1-C24 alkoxy, substituted or unsubstituted C1-C24 silyl, substituted or unsubstituted C6-C36 aryl, or a combination thereof, R³ is represented by any one of hydrogen, deuterium, halogen, —CN, substituted or unsubstituted C1-C24 alkyl, substituted or unsubstituted C1-C24 cycloalkyl, substituted or unsubstituted C3-C24 heterocycloalkyl, substituted or unsubstituted C1-C24 alkoxy, substituted or unsubstituted C6-C36 aryl, C6-C36 heteroaryl, substituted or unsubstituted C6-C36 arylamino, substituted or unsubstituted C6-C36 heteroarylamino, substituted or unsubstituted C1-C24 alkylamino, or a combination thereof, the heteroatoms in the heterocycloalkyl, heteroaryl groups can be selected from N, O, S or Si; the heteroatom in the heteroarylamino can be selected from O, S or Si;
R⁴ and R⁵ are each independently represented by one of hydrogen, deuterium, halogen, —CN, substituted or unsubstituted C1-C24 alkyl, substituted or unsubstituted C1-C24 cycloalkyl, substituted or unsubstituted C3 to C24 heterocycloalkyl, substituted or unsubstituted C1-C24 alkoxy, substituted or unsubstituted C6-C36 aryl, or a combination thereof, when a substituent is present in the foregoing groups, the substituents are each independently selected from any one of deuterium, halogen, —CN, C1-C10 alkyl, C3-C10 cycloalkyl, C6-C30 aryl, or a combination thereof.

2. The phosphorescent material according to claim 1, wherein all the hydrogen atoms in Formula (I) may be substituted with deuterium atoms.

3. The phosphorescent material according to claim 1, wherein any two substituents of Formula (I) can be joined or fused together to form a ring.

4. The phosphorescent material according to claim 1, wherein two or more of R¹, R², R³, R⁴, and R⁵ in Formula (I) can be selectively linked to form a ring.

5. The phosphorescent material according to claim 1, wherein R¹ and R² in Formula (I) is each independently represented by any one of hydrogen, deuterium, F, —CN, methyl, ethyl, propyl, isopropyl, tert-butyl, phenyl, methoxy, trimethylsilane, or a combination thereof.

6. The phosphorescent material according to claim 1, wherein R³ in Formula (I) is represented by any one of hydrogen, deuterium, F, —CN, methyl, ethyl, propyl, isopropyl, tert-butyl, heptyl, cyclopentane, pyridyl, carbazolyl, diphenylamino, phenothiazinyl, phenoxazinyl, phenyl, methoxy, trimethylsilyl, benzofuranyl, benzothienyl, pyrrolidinyl, 1,1 dimethylindenyl, or a combination thereof.

7. The phosphorescent material according to claim 1, wherein R⁴ and R⁵ in Formula (I) are each independently represented by any one of hydrogen, deuterium, F, —CN, methyl, ethyl, propyl, isopropyl, tert-butyl, heptyl, cyclopentanyl, cyclopentenyl, phenyl, methoxy, trimethylsilyl, benzofuranyl, benzothienyl, pyrrolidinyl, 1,1 dimethylindenyl, or a combination thereof.

8. A bivalent platinum or palladium metal complex phosphorescent material based on dibenzothiophene coordination, wherein the phosphorescent material is selected from one of the following structures:

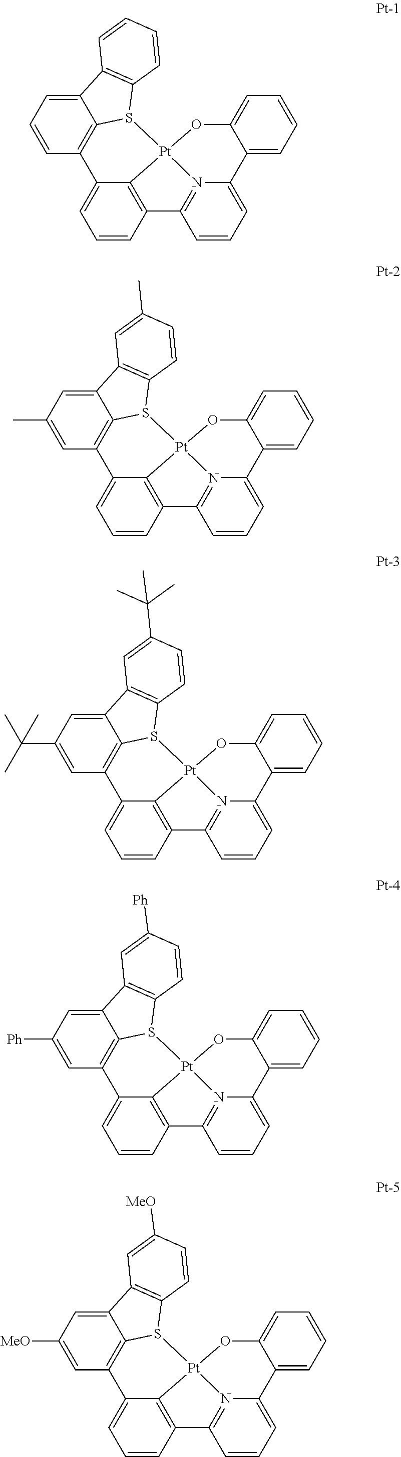

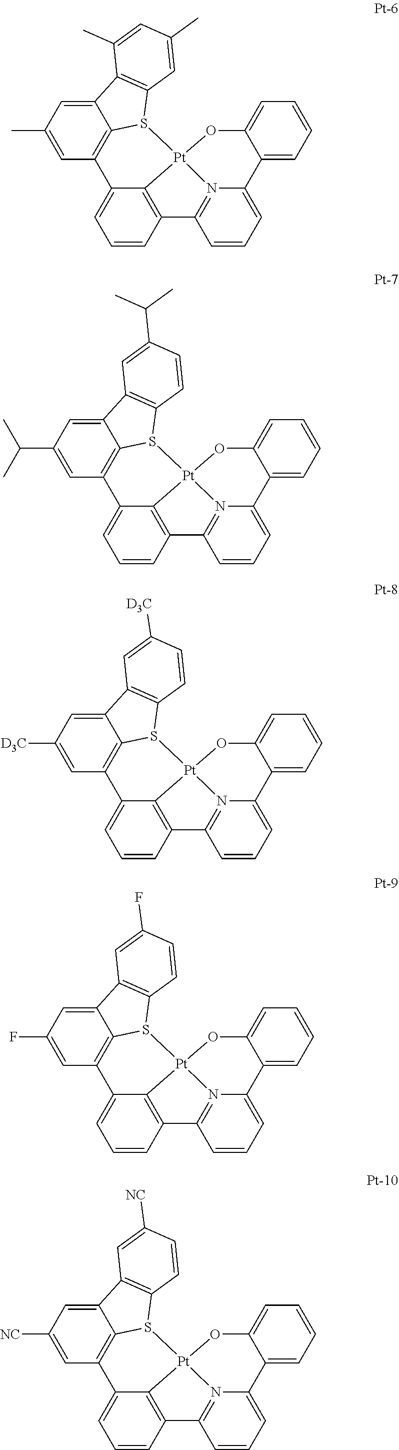

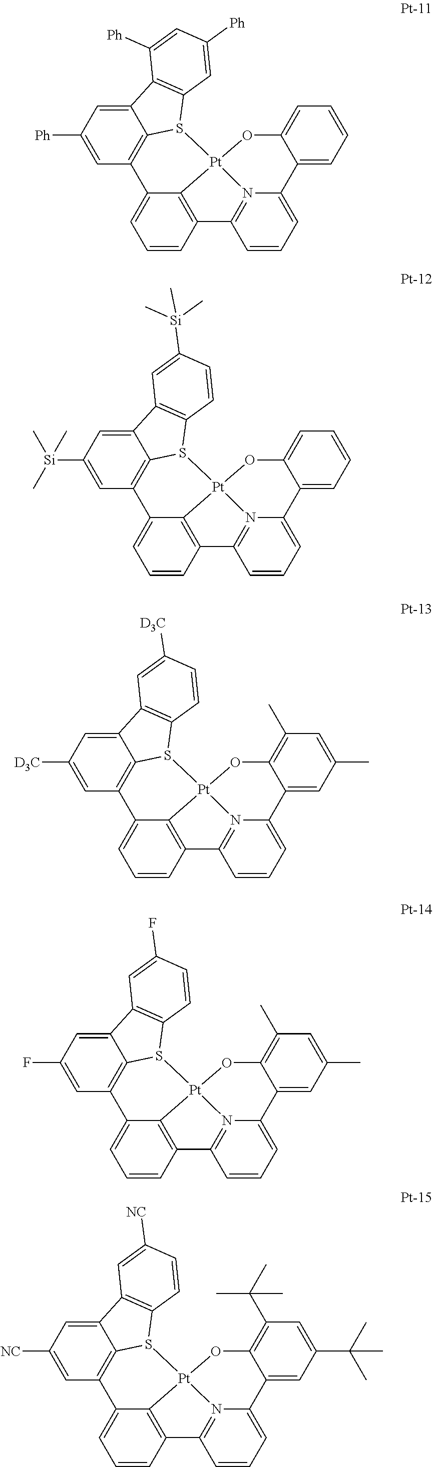

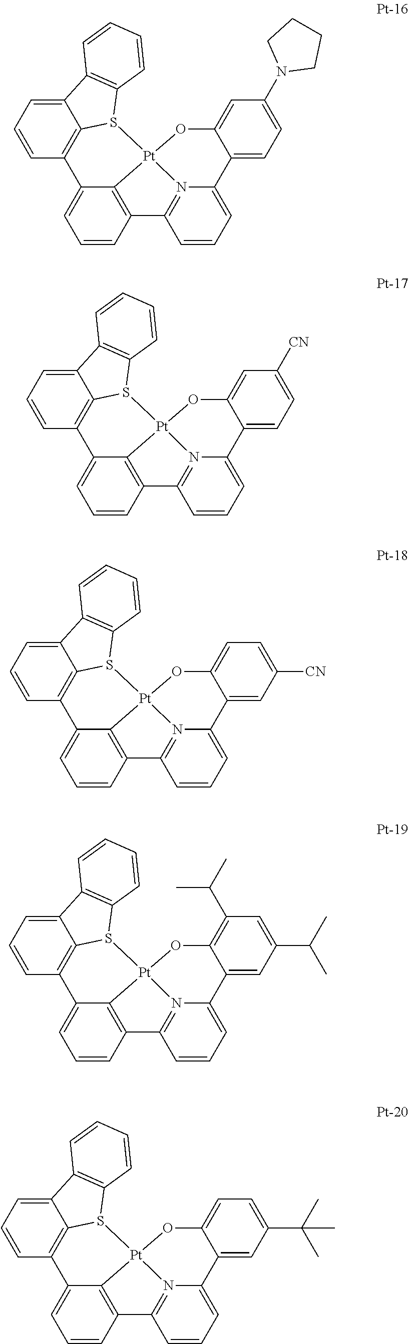

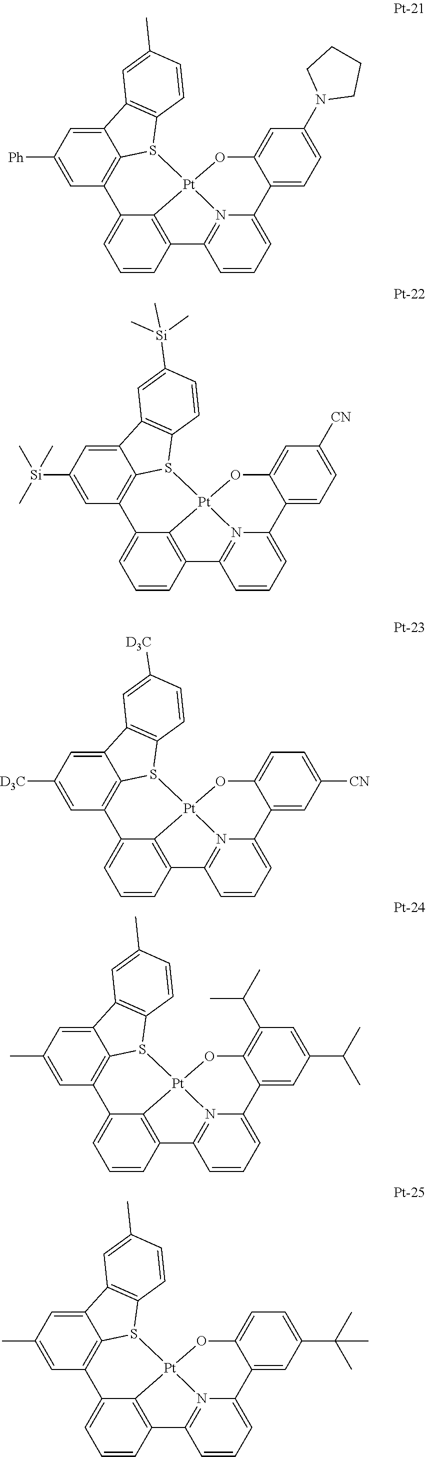

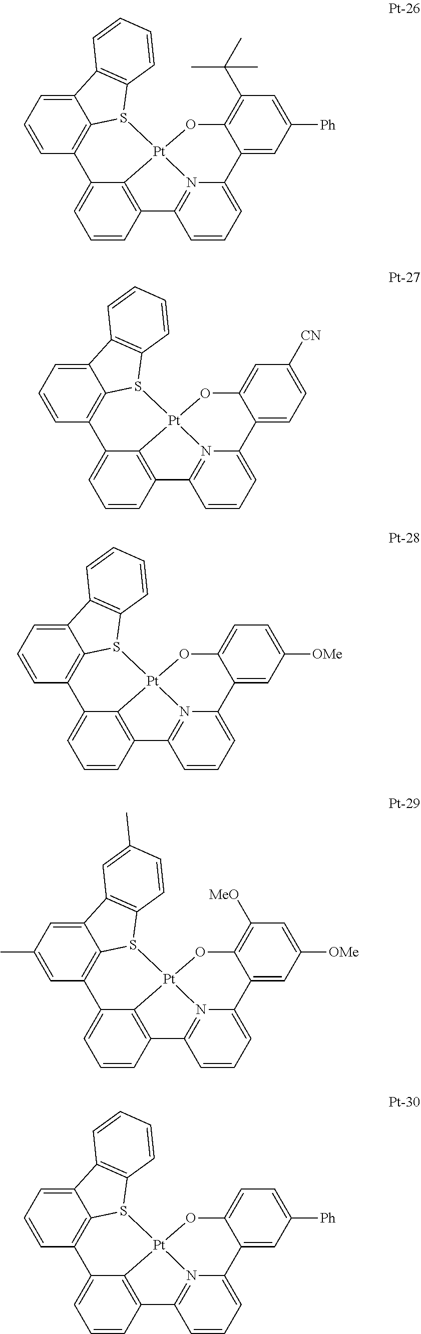

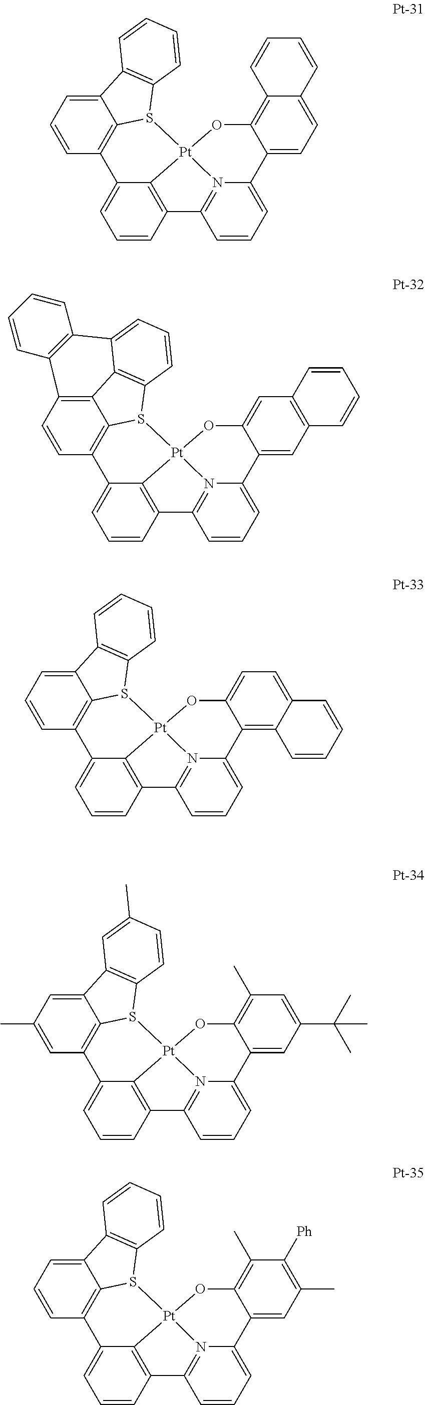

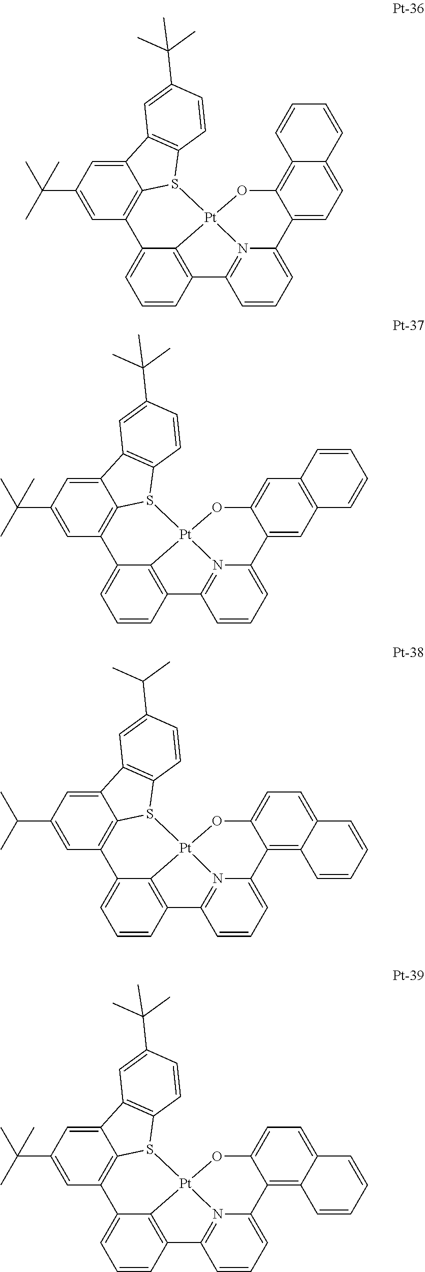

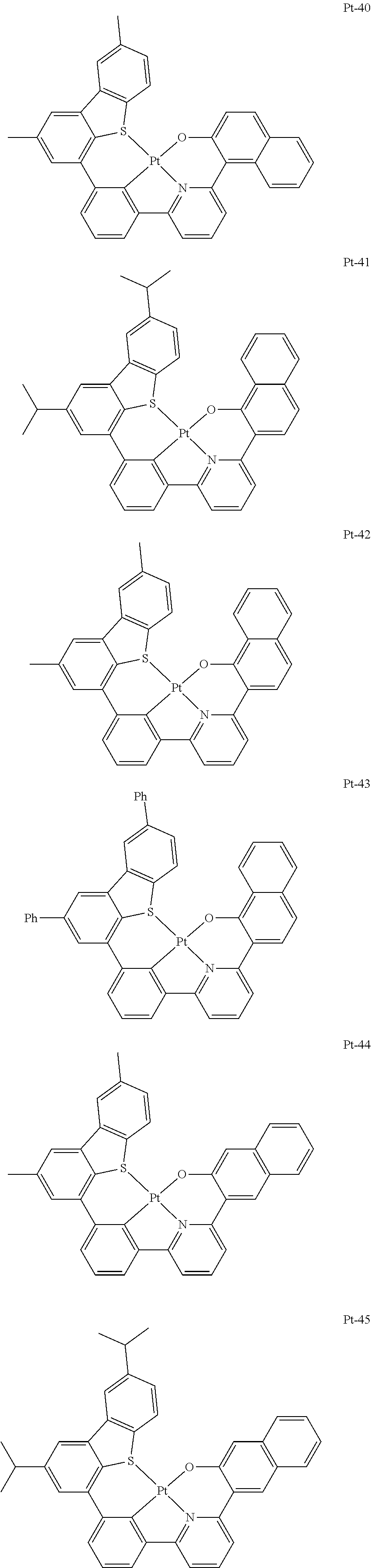

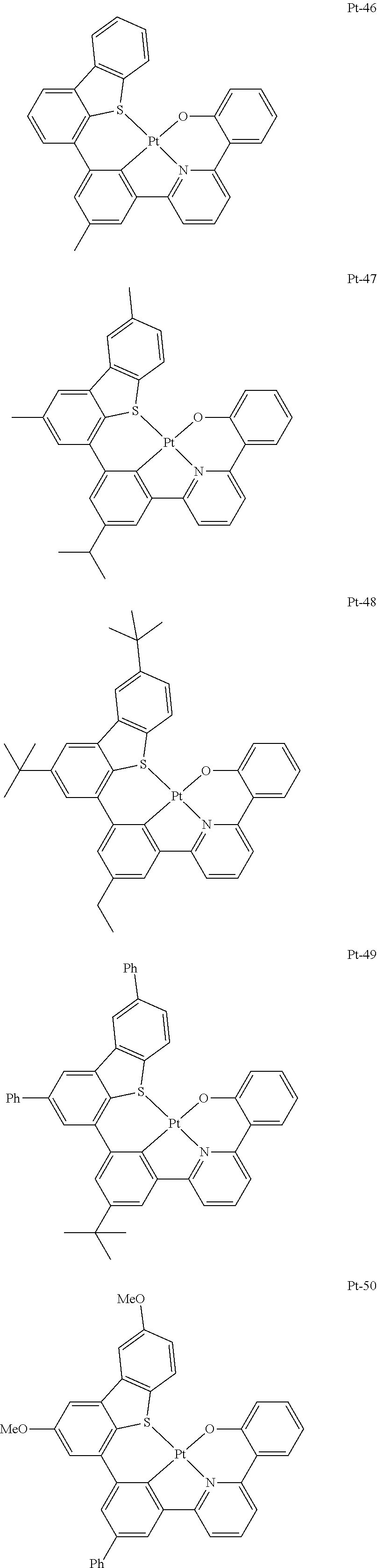

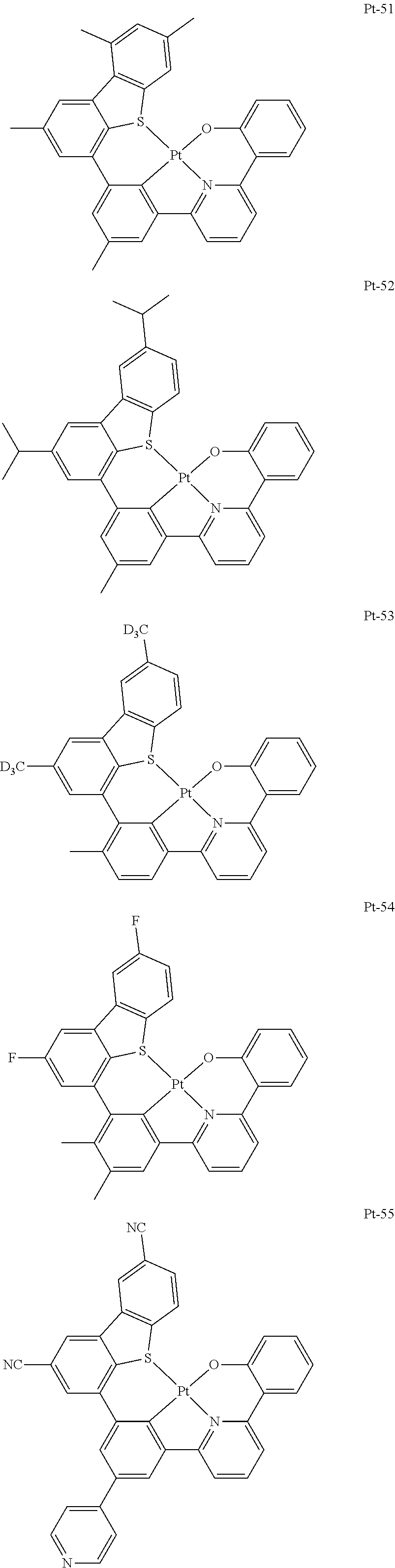

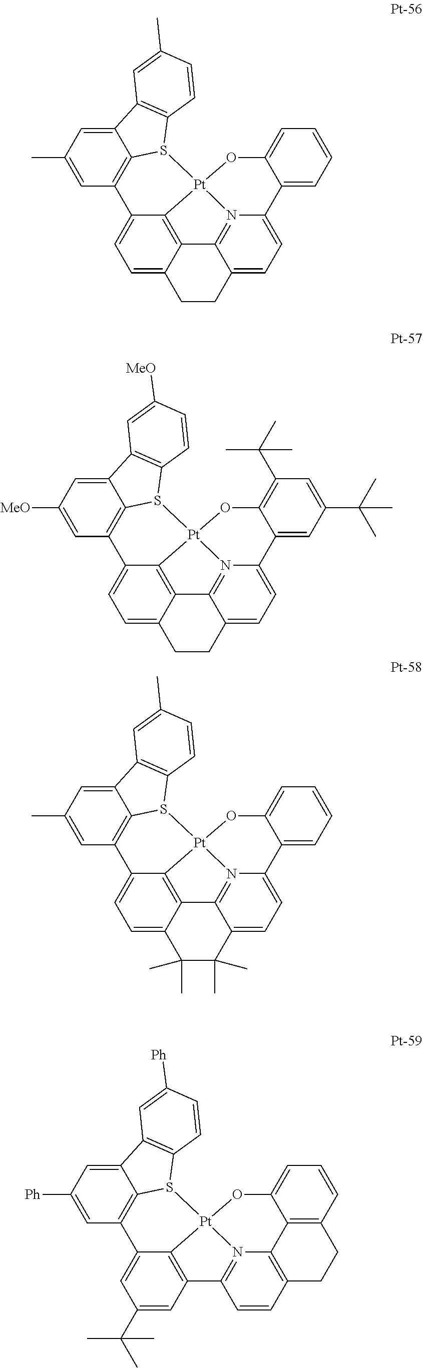

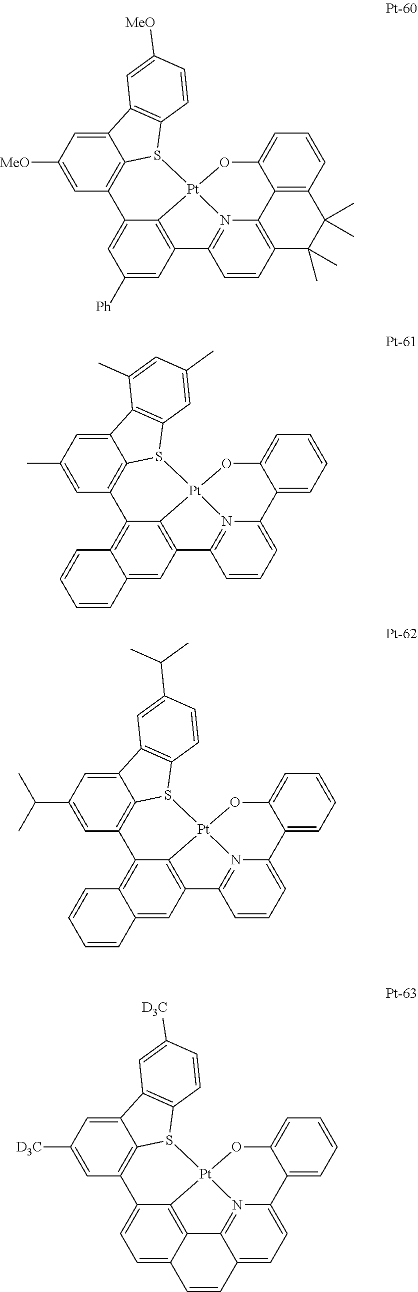

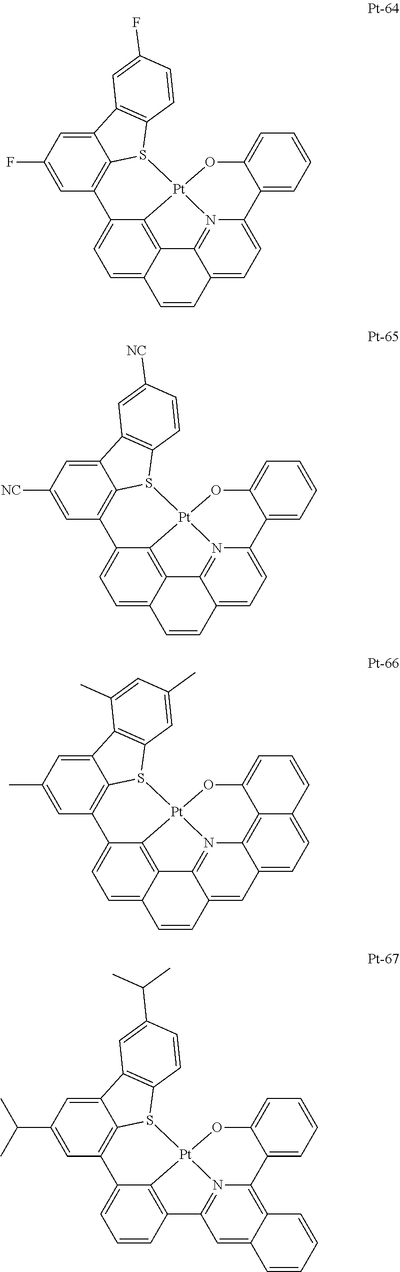

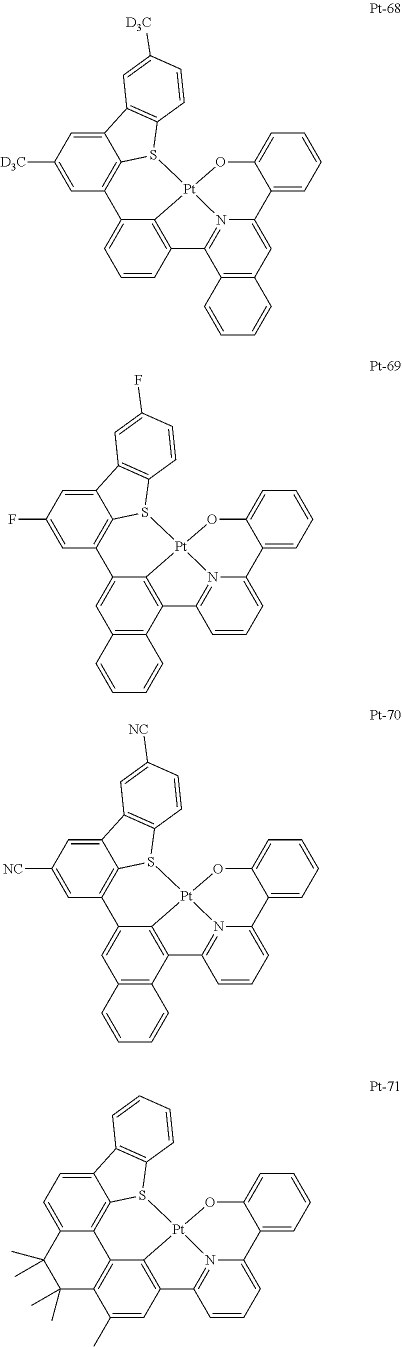

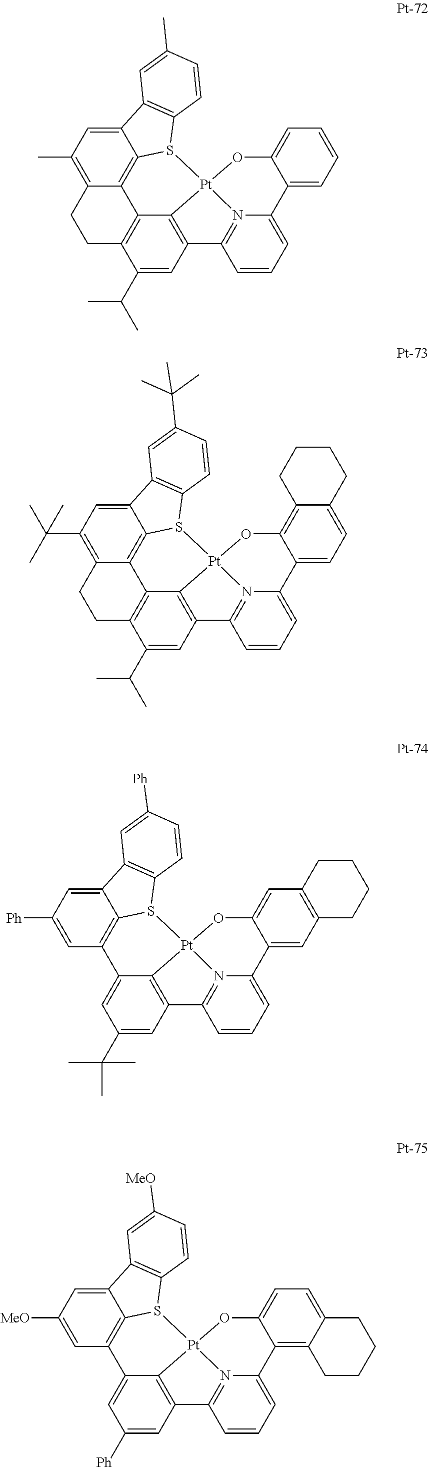

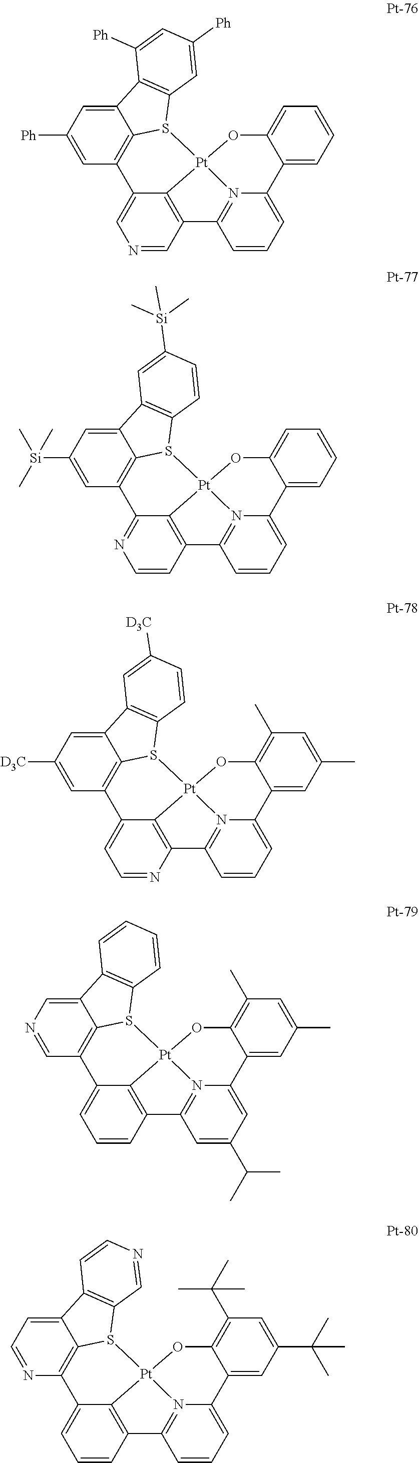

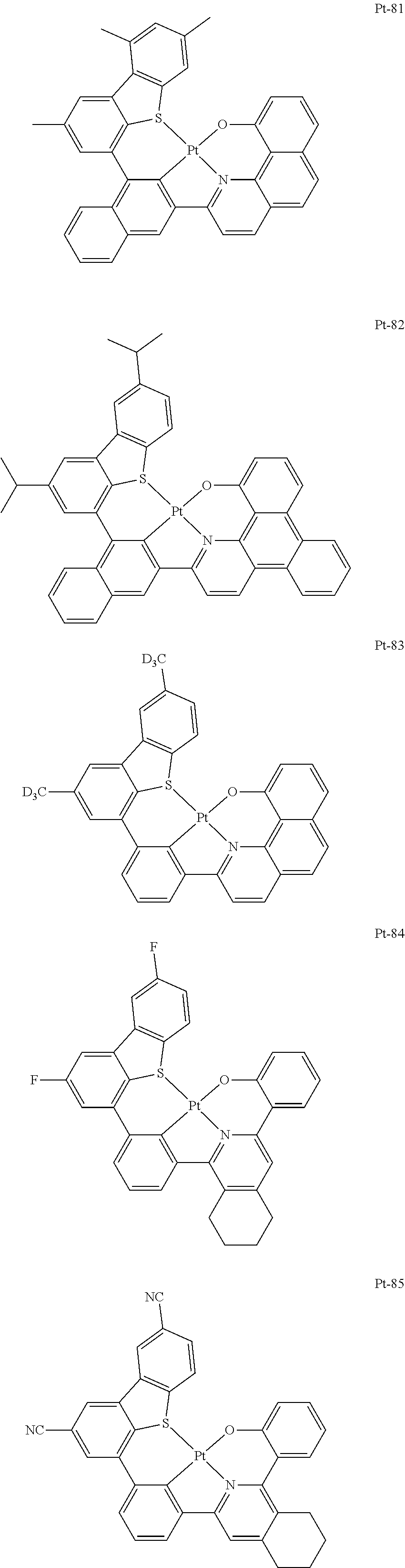

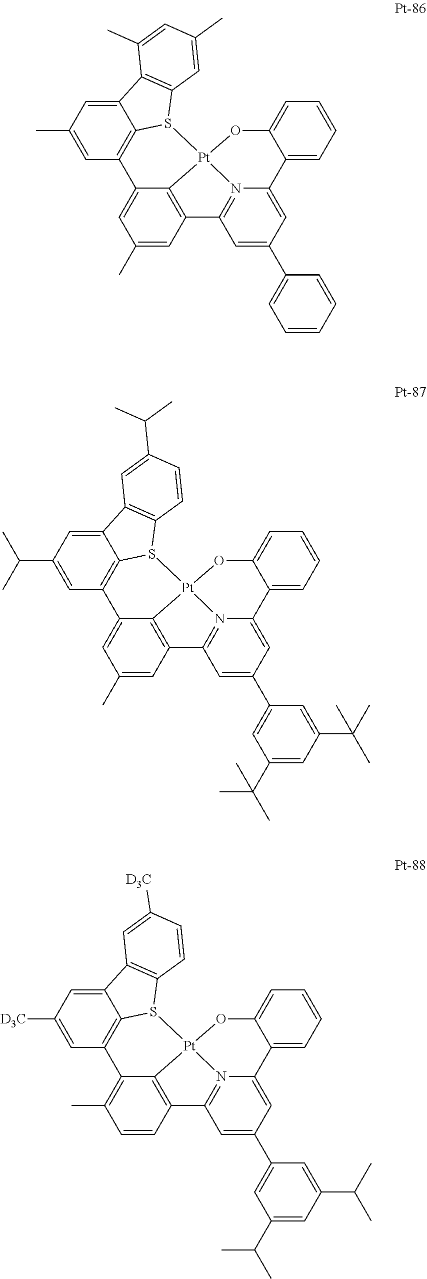

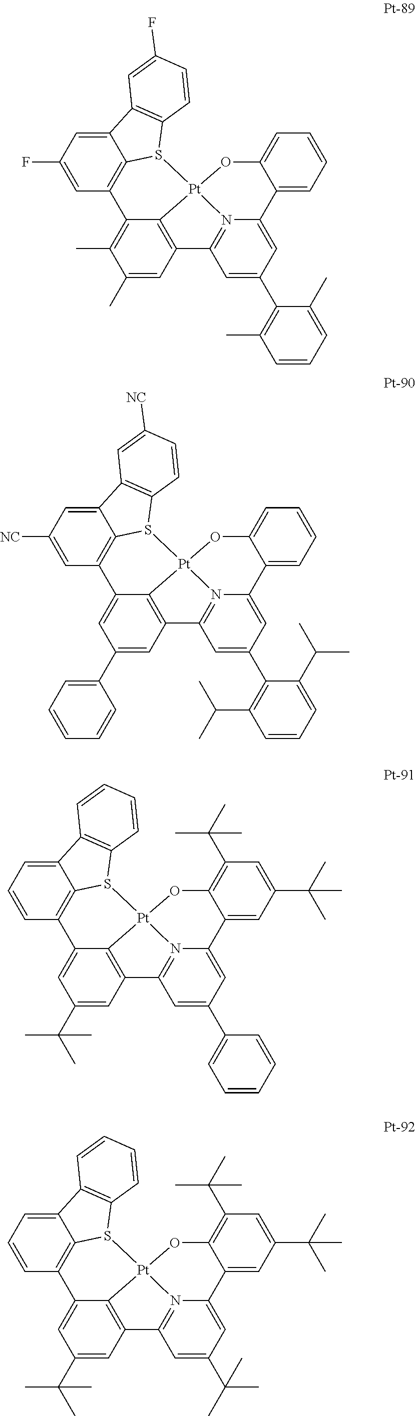

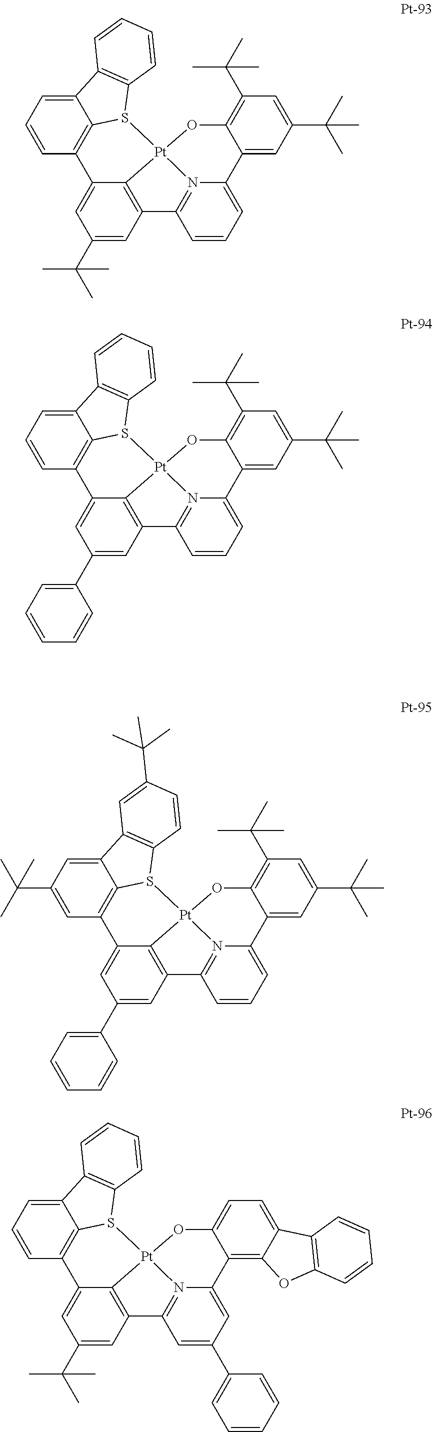

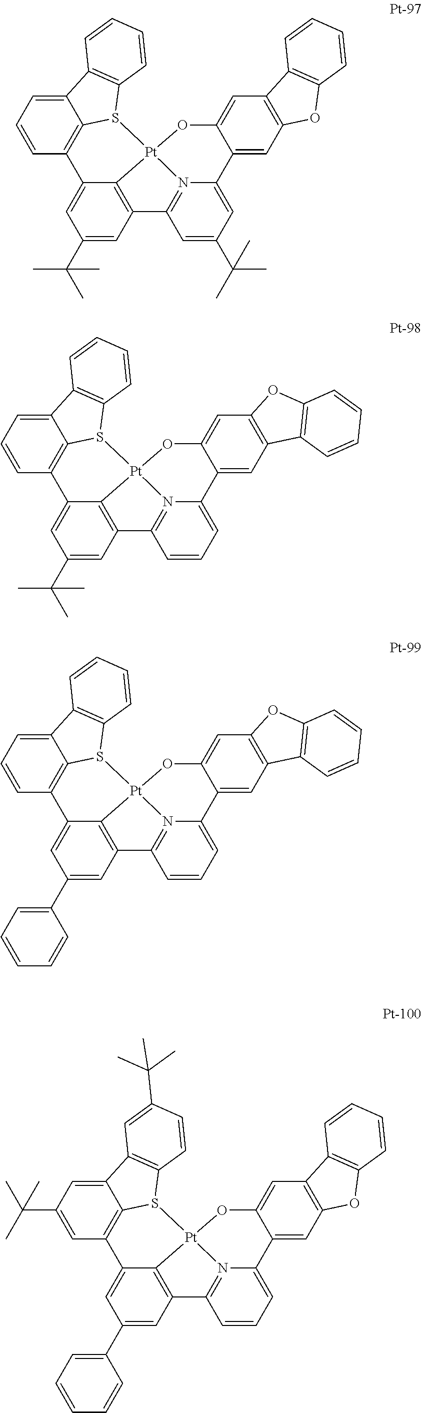

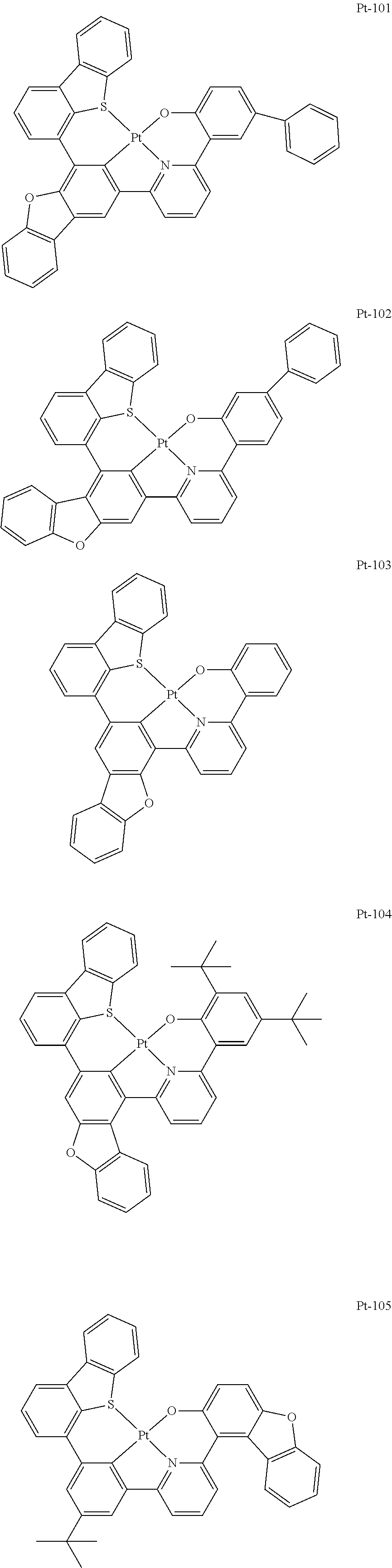

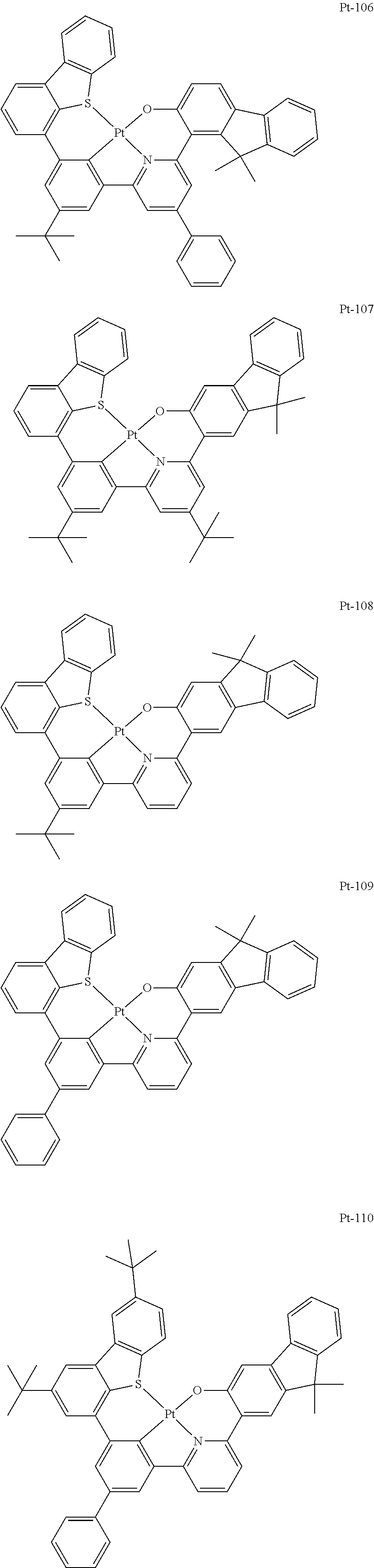

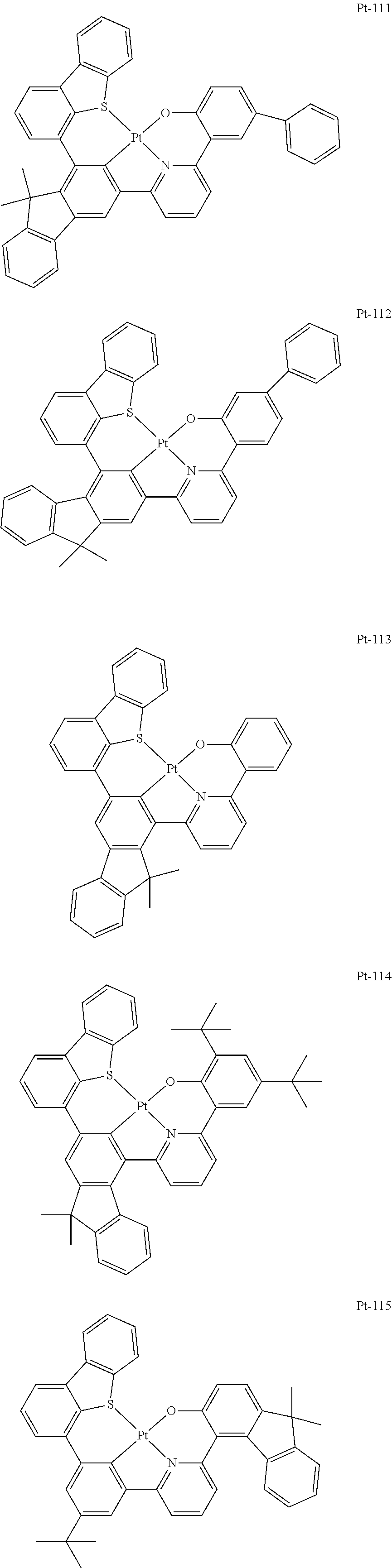

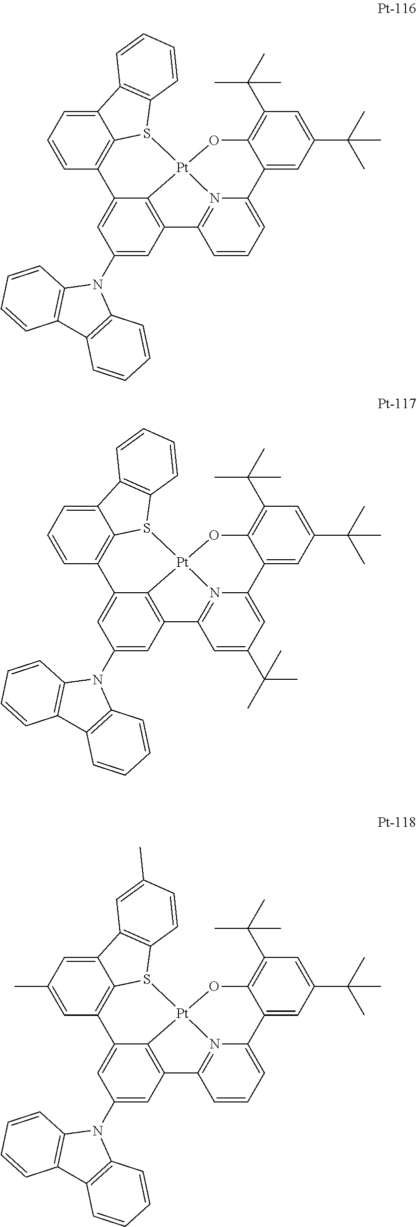

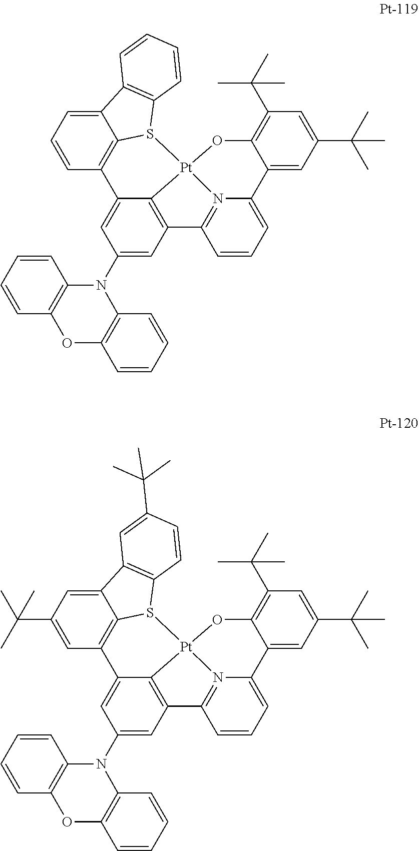

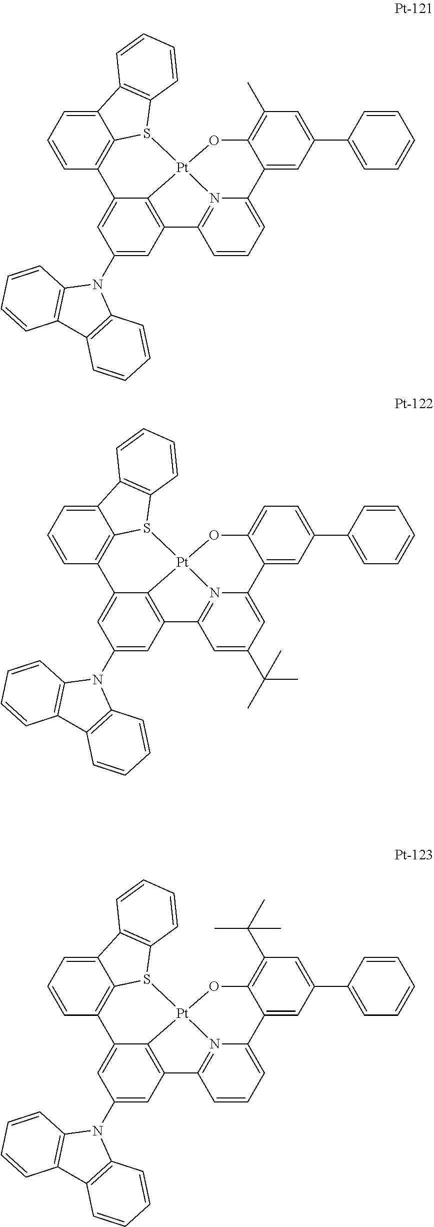

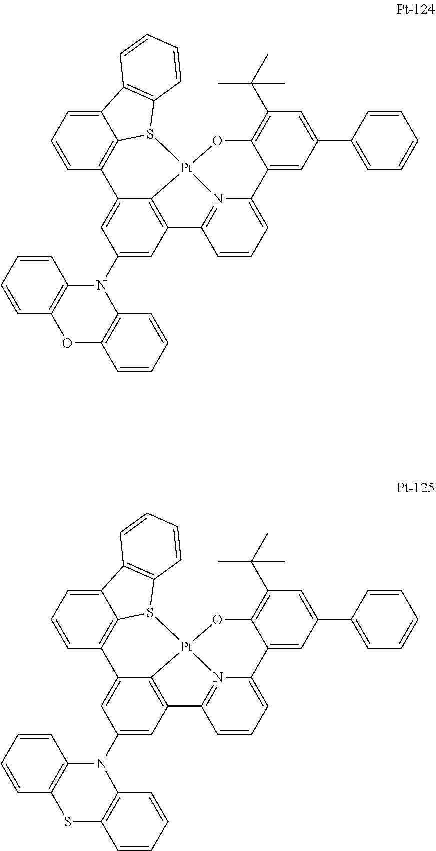

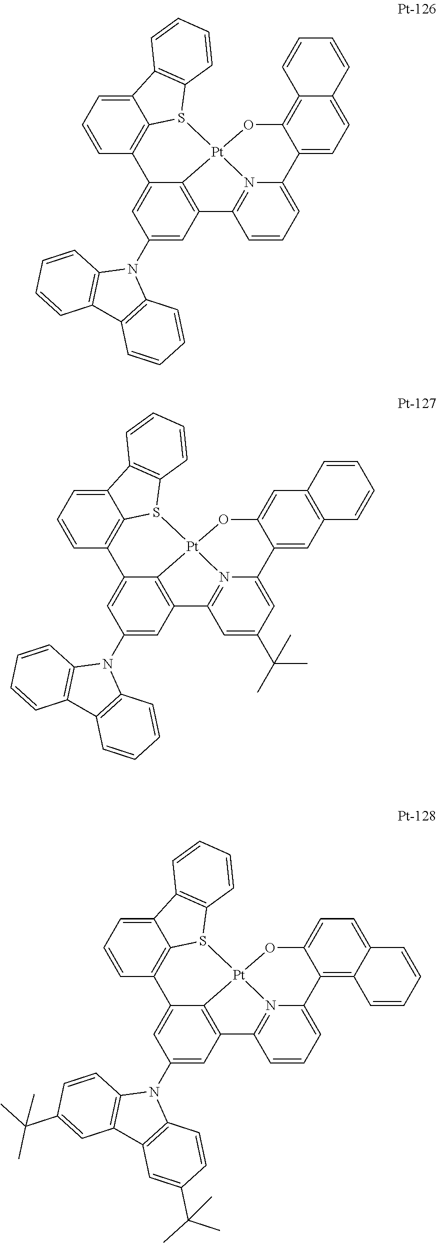

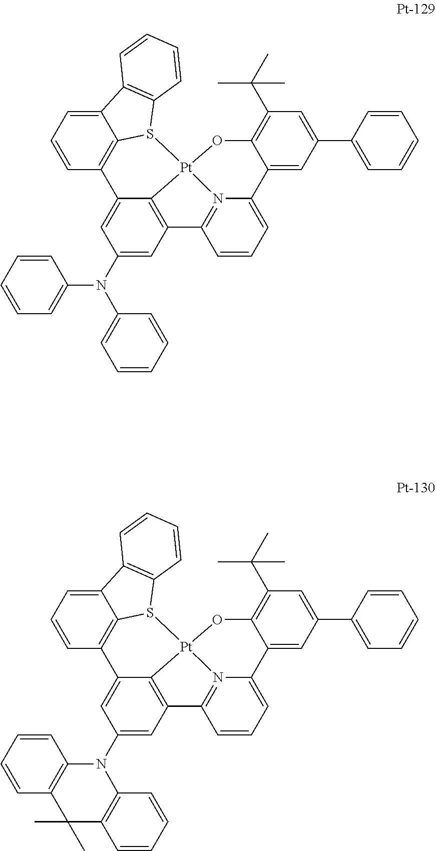

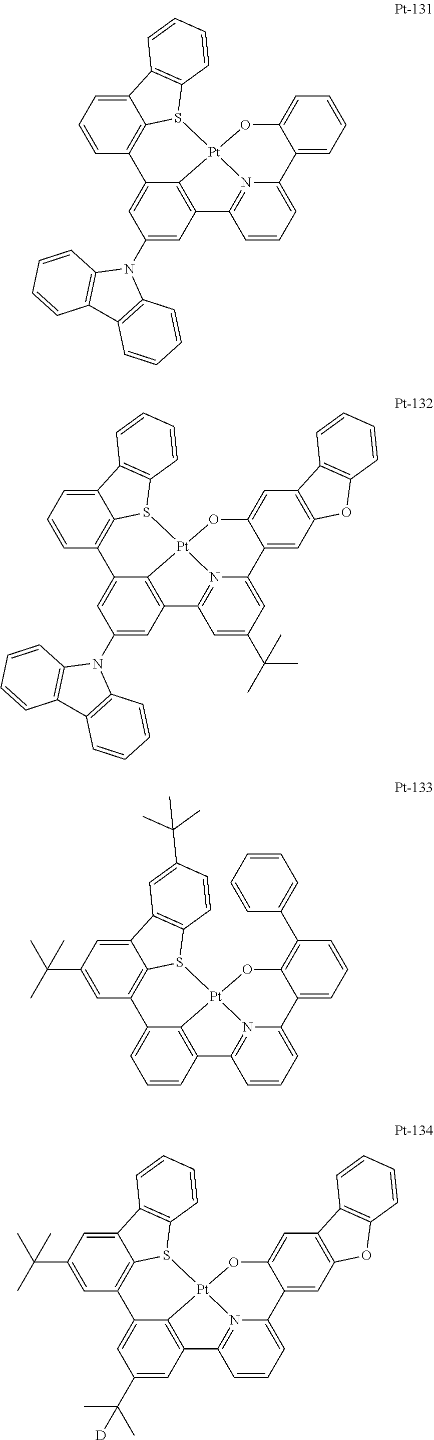

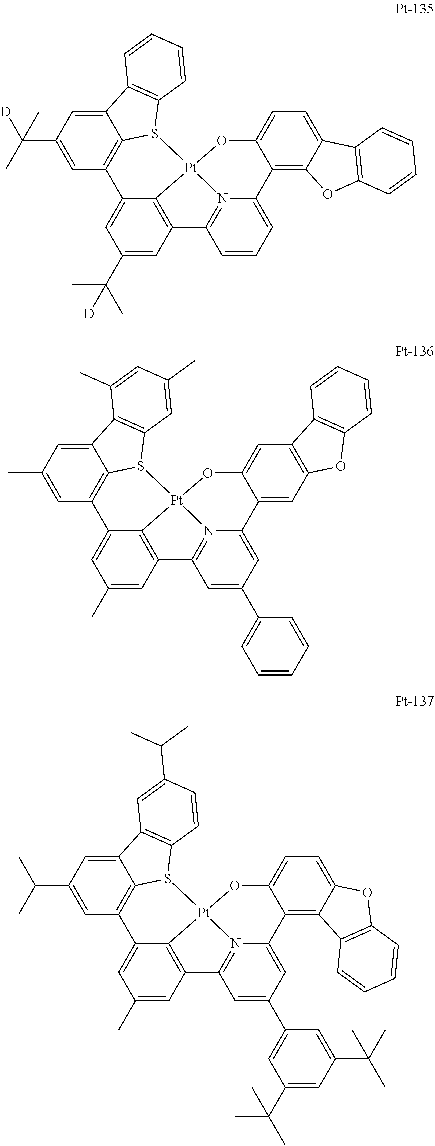

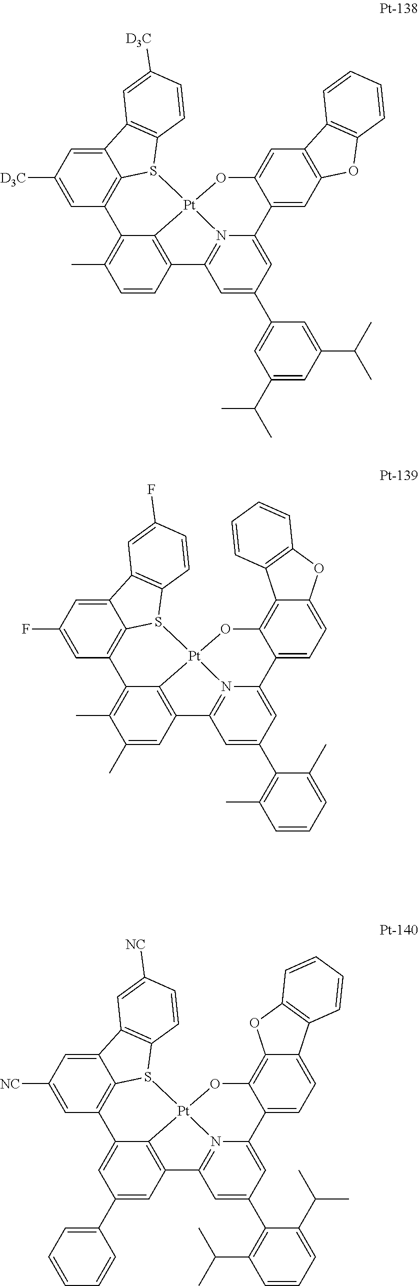

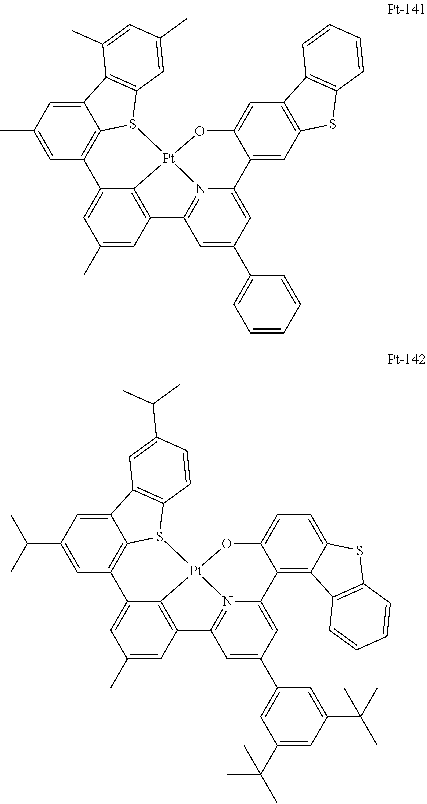

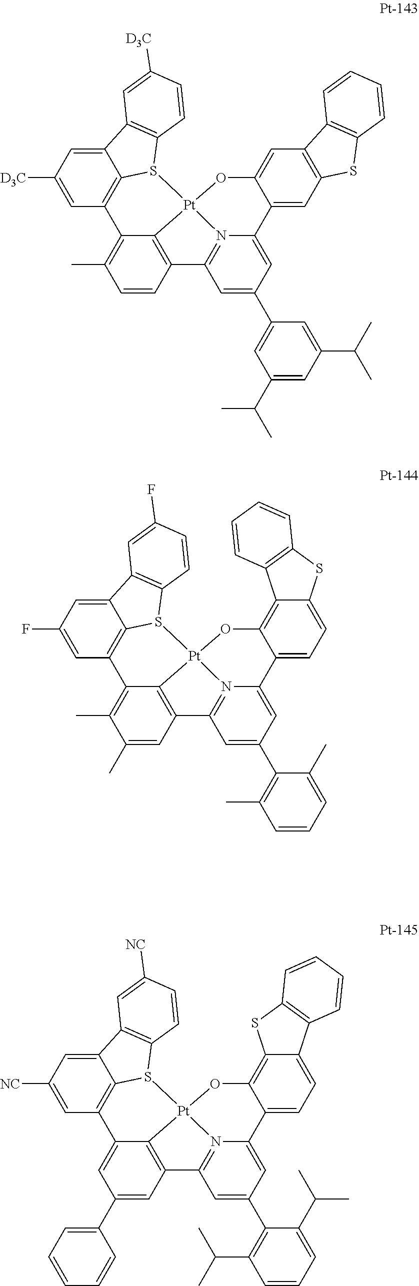

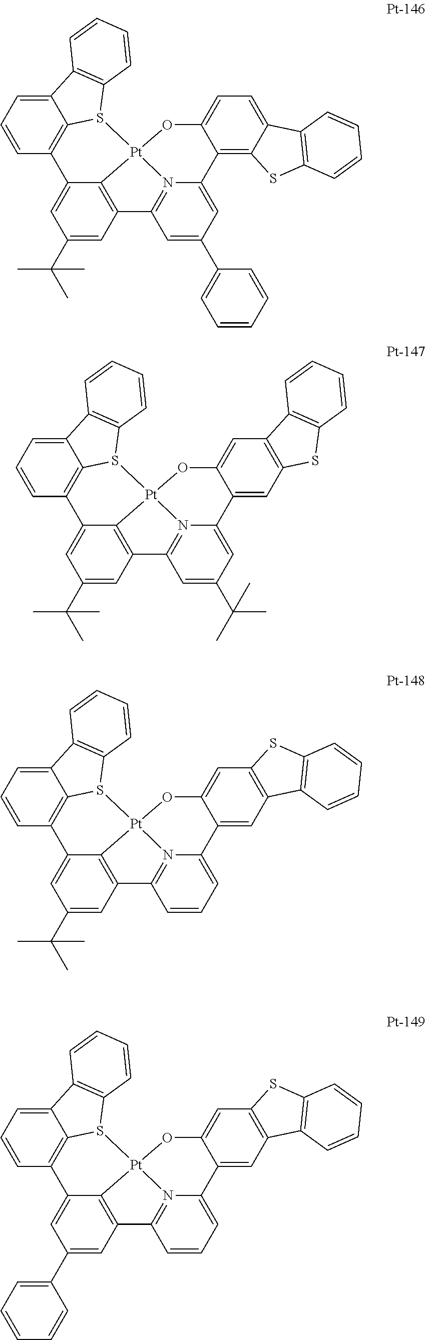

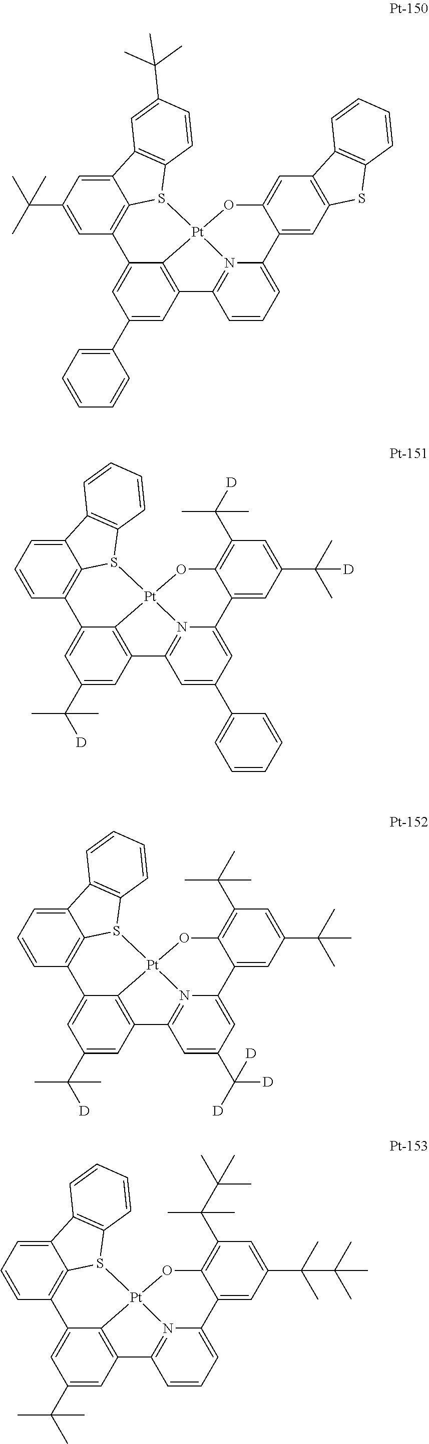

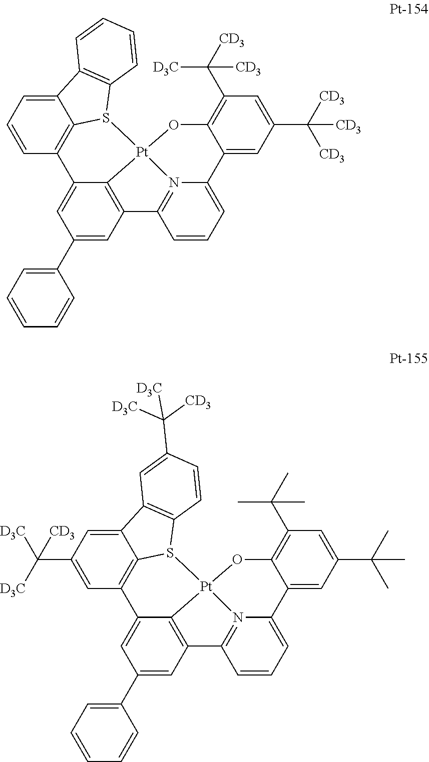

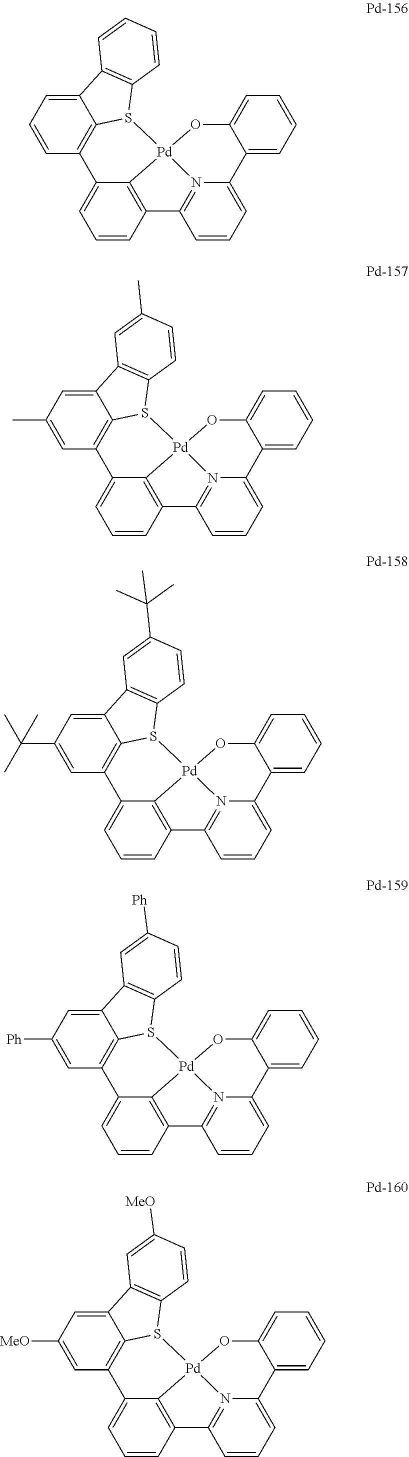

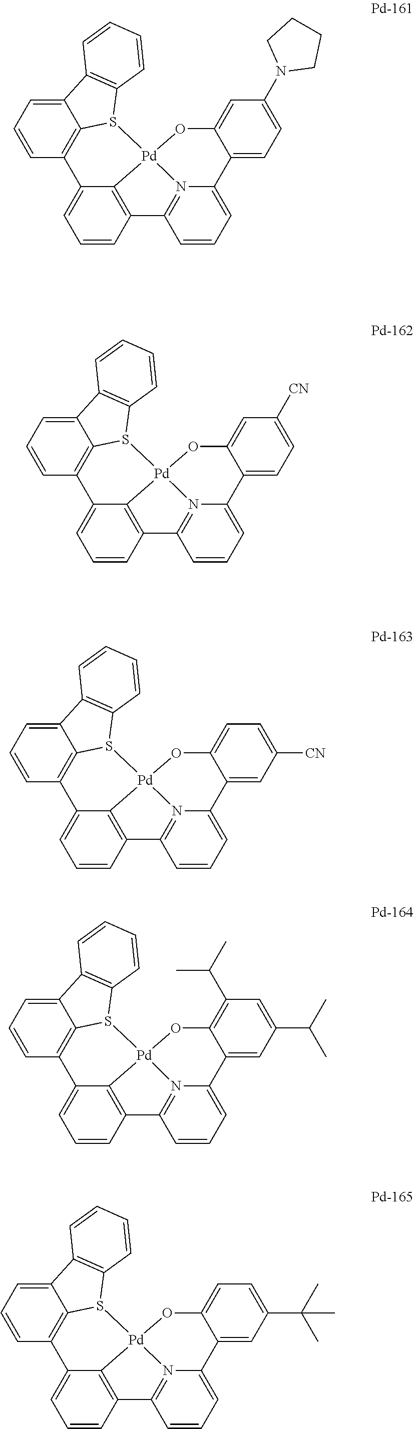

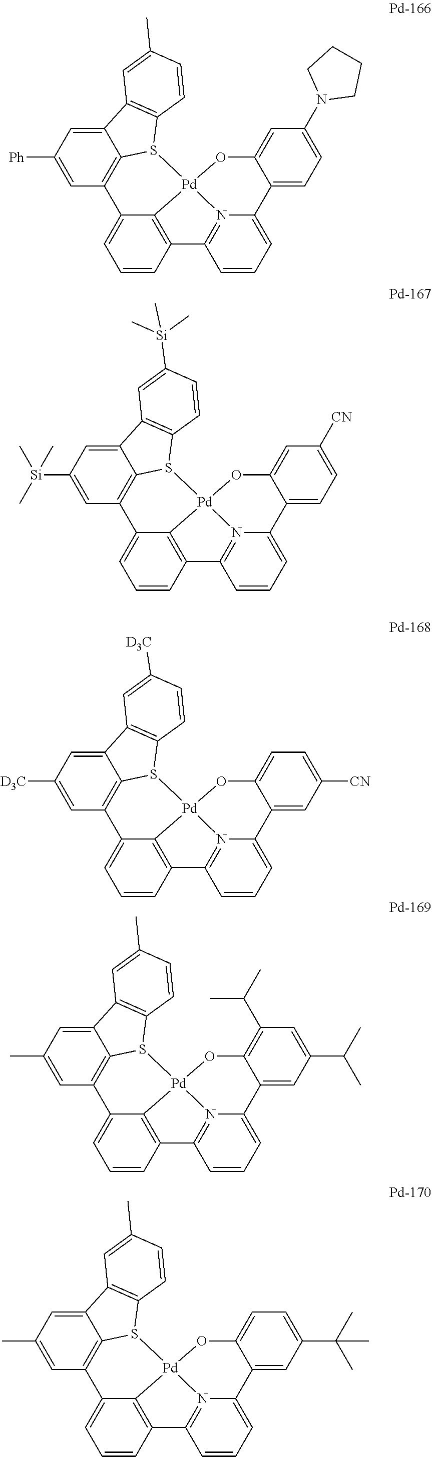

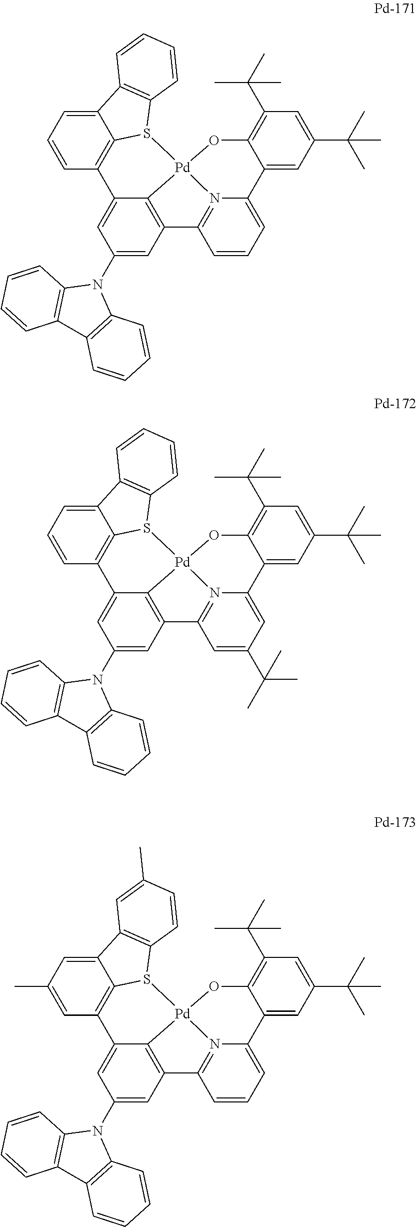

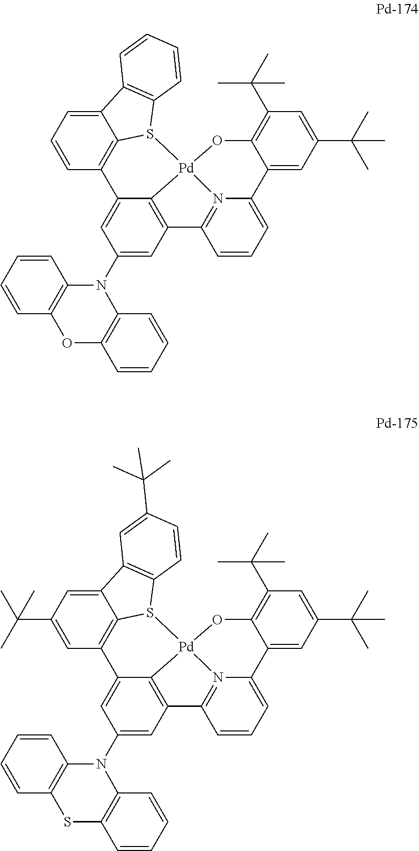

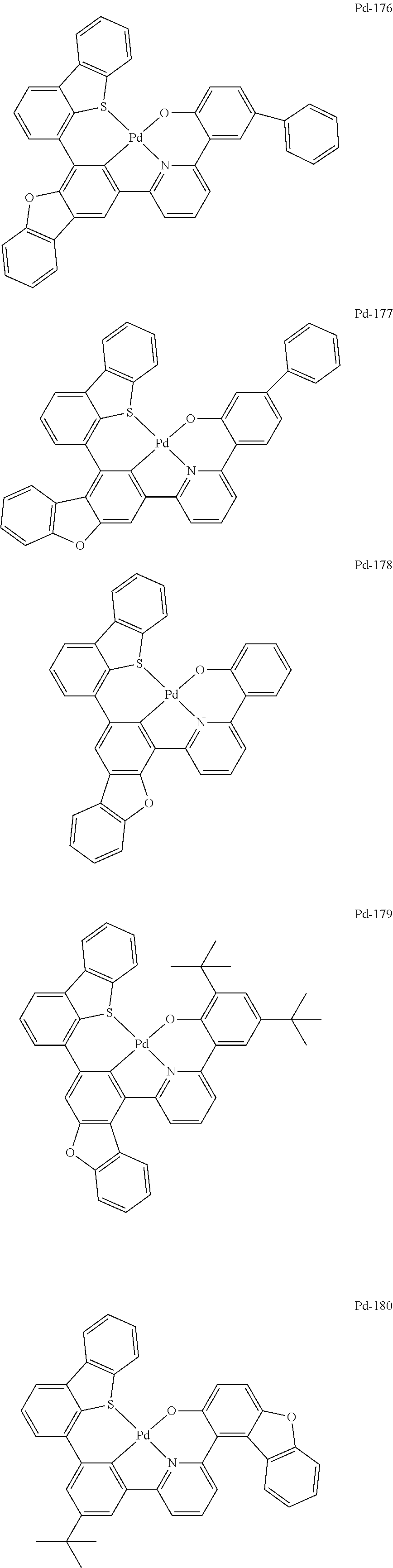

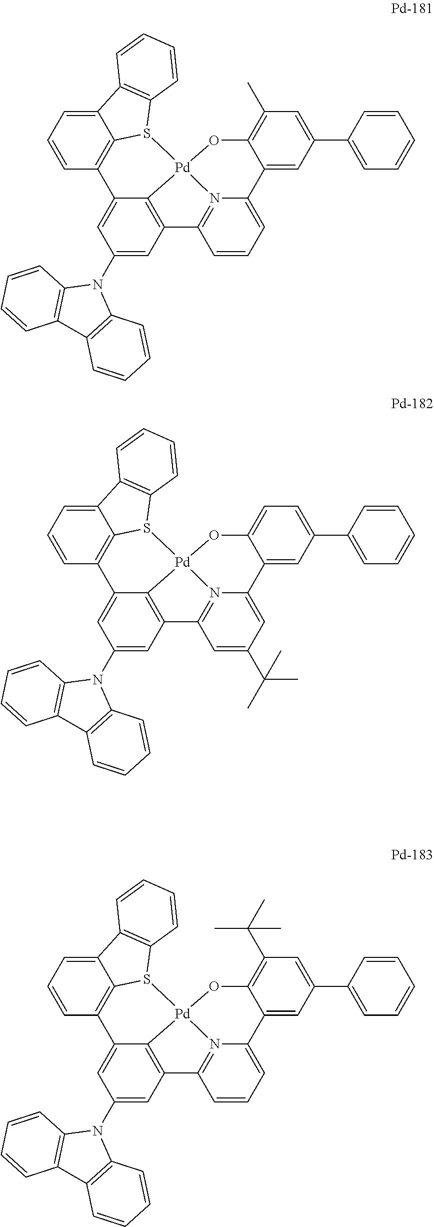

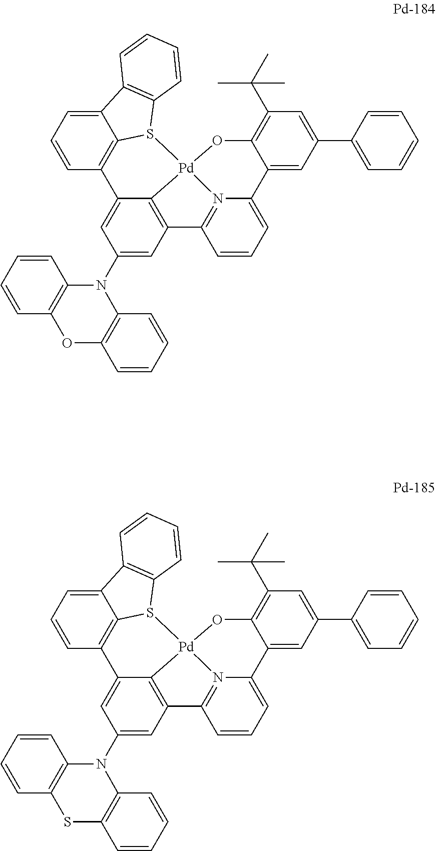

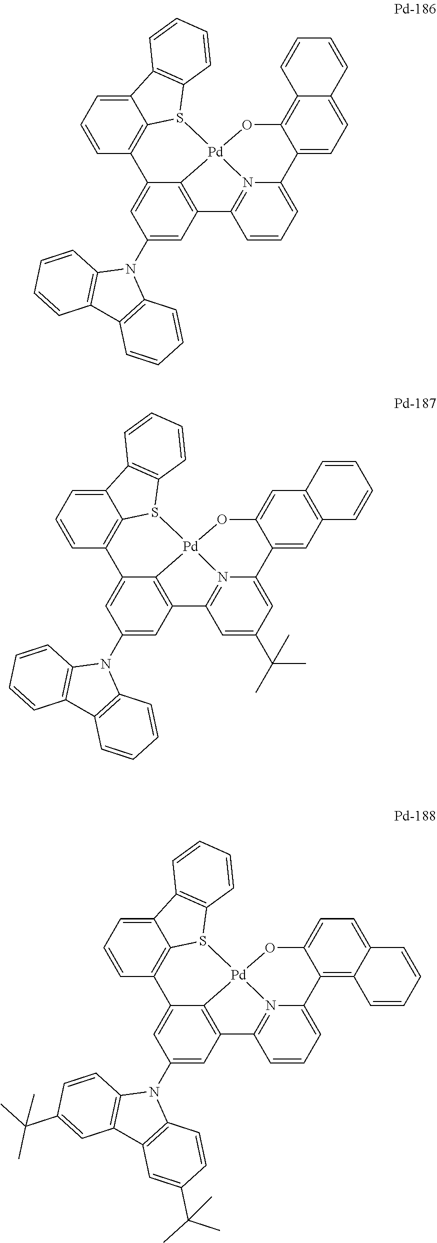

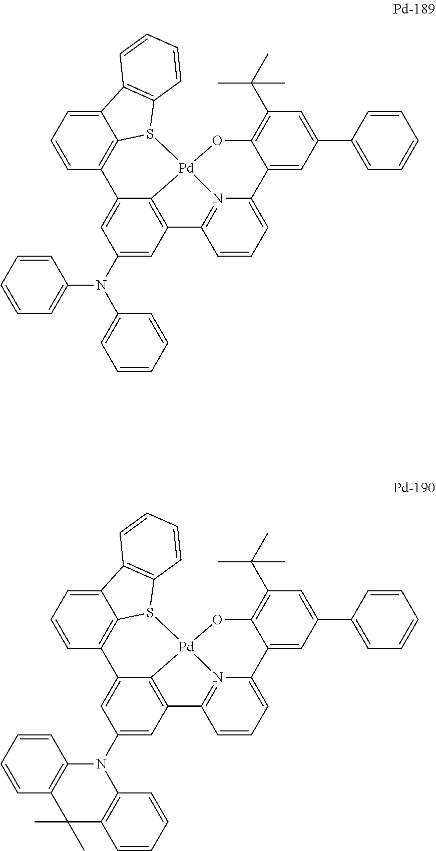

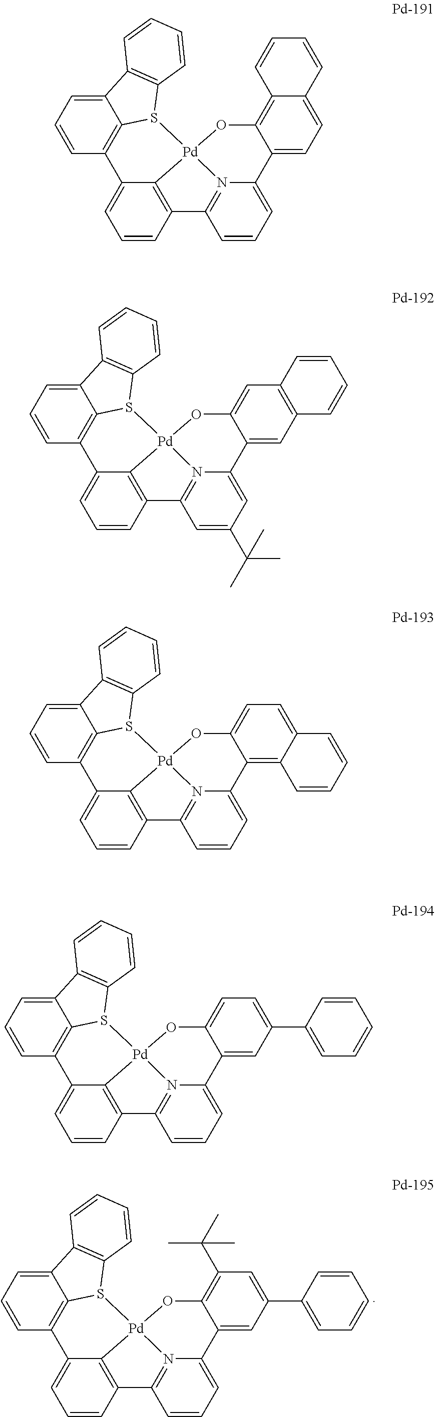

9. Use of the bivalent platinum or palladium metal complex phosphorescent material based on dibenzothiophene coordination according to claim 1 as a temperature-responsive light-emitting material.

10. An optical thermometer, comprising the bivalent platinum or palladium metal complex phosphorescent material based on dibenzothiophene coordination according to claim 1.

11. Use of the bivalent platinum or palladium metal complex phosphorescent material based on dibenzothiophene coordination according to claim 1 for producing an organic luminous element.

12. The use according to claim 11, wherein the organic luminous element is an organic light-emitting diode, light-emitting diode, or light-emitting electrochemical cell.

13. An organic light-emitting diode, comprising:
an anode;
a cathode; and
an organic layer disposed between the anode and the cathode, wherein the organic layer comprises the bivalent platinum or palladium metal complex phosphorescent material based on dibenzothiophene coordination according to claim 1.

14. A consumer product, comprising the organic light-emitting diode according to claim 12.
